(19) United States
(12) Patent Application Publication
(10) Pub. No.: US 2026/0190798 A1
(43) Pub. Date: Jul. 2, 2026

(54) DISPLAY DEVICE

(71) Applicant: LG DISPLAY CO., LTD., Seoul (KR)

(72) Inventors: JaeWon LEE, Paju-si (KR); Seunghwan KIM, Paju-si (KR); Juyoung PARK, Paju-si (KR)

(73) Assignee: LG DISPLAY CO., LTD., Seoul (KR)

(21) Appl. No.: 19/436,387

(22) Filed: Dec. 30, 2025

(30) Foreign Application Priority Data
Dec. 30, 2024 (KR) 10-2024-0199904

(51) Int. Cl. H10K 59/80; G06F 3/044; H10K 59/131; H10K 59/40

(52) U.S. Cl. CPC H10K 59/874; G06F 3/0446; H10K 59/131; H10K 59/40; H10K 59/873

(57) ABSTRACT

A display device can include a substrate including a display area and a non-display area outside of the display area, the display area including subpixels, a dam disposed in the non-display area, an encapsulation layer disposed on the subpixels and the dam, at least one auxiliary routing line disposed on a portion of the encapsulation layer, the at least one auxiliary routing line does not overlap with the dam, and a moisture preventing layer disposed on the encapsulation layer and overlapping with the dam. Also, the display device can further include a sensor interlayer insulating layer disposed on the at least one auxiliary routing line and the moisture preventing layer, and at least one touch routing line disposed on the sensor interlayer insulating layer and electrically connected to the auxiliary routing line.

### CROSS REFERENCE TO RELATED APPLICATION

This application claims priority to Korean Patent Application No. 10-2024-0199904, filed in the Republic of Korea on Dec. 30, 2024, the entirety of which is hereby incorporated by reference for all purposes as if fully set forth herein.

### BACKGROUND

### Technical Field

The present disclosure relates to electronic devices, and more specifically, to display devices.

### Discussion of Related Art

In today's information society, display devices for presenting images or visual information to users are increasingly important. The need for such display devices has caused display technology to be rapidly developed, and various types of display devices, such as a liquid crystal display (LCD) device, a light emitting diode (OLED) display device, and the like, have been developed and used.

Display devices increasingly employ a touch-based input interface capable of allowing users to easily input information or a command to the display devices in an intuitive and convenient manner. These touch-enabled display devices can recognize a touch applied by a touch object such as a finger, a pen, or the like on a display panel and perform input processing based on the recognized touch input.

For example, to provide such a touch function, display devices can include a plurality of touch electrodes disposed on a display panel. The display devices can sense a user's touch by driving the plurality of touch electrodes and detecting a change in capacitance formed when the touch is applied on the display panel.

The display devices can include various configurations for image display in addition to a configuration for touch sensing. Work has been progressing on implementing touch electrodes on the display panel in order to improve the performance of touch sensing without degrading the image display performance of display devices.

However, display devices with integrated touch sensors face several challenges in ensuring reliability and performance. For example, complex layering of components can introduce structural vulnerabilities that can lead to compromised electrical connections and sensor failures, particularly in areas that are subject to bending. Further, these complex assemblies are often susceptible to environmental degradation, especially from moisture, which can damage sensitive internal circuitry.

Thus, there exists a need for a display device having an improved configuration that can enhance the structural integrity and environmental resistance of display devices, reduce manufacturing defects, and improve their overall durability and operational lifespan.

Further, a need exists for display device having an configuration that can better reduce or prevent moisture from entering the inside of a display panel from an area outside of the display panel.

### SUMMARY OF THE DISCLOSURE

The present disclosure has been made in view of the above problems and it is an object of the present disclosure to provide a display device that can enhance the structural integrity and environmental resistance of display devices, and improve durability and operational lifespan.

One or more aspects of the present disclosure can provide a display device that includes a moisture preventing layer, and is capable of reducing or preventing moisture from entering the inside of a display panel from an area outside of the display panel.

One or more aspects of the present disclosure can provide a display device that includes a sensor interlayer insulating layer with a sufficient thickness, and is capable of compensating for a step difference between upper and lower surfaces (or edges) of a dam structure.

One or more aspects of the present disclosure can provide a display device capable of eliminating or reducing the occurrence of short circuiting or disconnection (or separation, peeling) of touch lines by compensating for a step difference between upper and lower surfaces (or edges) of a dam structure.

One or more aspects of the present disclosure can provide a display device capable of enabling process optimization by maintaining an appropriate exposure process.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can include a substrate including a display area and a non-display area outside of the display area, display area including subpixels, a dam disposed in the non-display area, an encapsulation layer disposed on the subpixels and the dam, at least one auxiliary routing line disposed on a portion of the encapsulation layer, the at least one auxiliary routing line can not overlap with the dam, a moisture preventing layer disposed on the encapsulation layer and overlapping with the dam, a sensor interlayer insulating layer disposed on the at least one auxiliary routing line and the moisture preventing layer, and a touch routing line disposed on the sensor interlayer insulating layer and electrically connected to the auxiliary routing line.

According to the one or more example embodiments described herein, a display device can include a plurality of subpixels disposed in a display area of a substrate, a dam disposed in a non-display area of the substrate located outside of the display area, adjacent auxiliary routing lines disposed on opposite sides of the dam, the adjacent auxiliary routing lines being separated from each other, a moisture preventing layer disposed between the adjacent auxiliary routing lines and overlapping with the dam, a sensor interlayer insulating layer extending across the adjacent auxiliary routing lines and the moisture preventing layer, and a touch routing line disposed on the sensor interlayer insulating layer and electrically connected between the adjacent auxiliary routing lines.

According to one or more aspects of the present disclosure, a display device can be provided that is capable of reducing or preventing moisture from entering the inside of a display panel from an area outside of the display panel by including a moisture preventing layer.

According to one or more aspects of the present disclosure, a display device can be provided that is capable of compensating for a step difference between upper and lower surfaces (or edges) of a dam structure by including a sensor interlayer insulating layer with a sufficient thickness.

According to one or more aspects of the present disclosure, a display device can be provided that is capable of eliminating or reducing the occurrence of short circuiting or disconnection (or separation) of touch lines by compensating for a step difference between upper and lower surfaces (or edges) of a dam structure.

According to one or more aspects of the present disclosure, a display device can be provided that is capable of enabling process optimization by maintaining an appropriate exposure process.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to aspects of the present disclosure;

FIG. 2 illustrates an example display panel according to aspects of the present disclosure;

FIG. 3 is an example cross-sectional view of a subpixel included in the display device according to aspects of the present disclosure;

FIG. 4 illustrates an example touch sensor structure included in the display device to aspects of the present disclosure;

FIG. 5 is an example enlarged view of area A of FIG. 4 according to aspects of the present disclosure;

FIG. 6 is an example cross-sectional view taken along line I-I′ in FIG. 5 according to aspects of the present disclosure;

FIG. 7 is another example enlarged view of area A of FIG. 4 according to aspects of the present disclosure;

FIG. 8 is an example cross-sectional view taken along line II-II′ in FIG. 7 according to aspects of the present disclosure;

FIG. 9 is another example enlarged view of area A of FIG. 4 according to aspects of the present disclosure;

FIG. 10 is an example cross-sectional view taken along line III-III′ in FIG. 9 according to aspects of the present disclosure;

FIG. 11 is an example enlarged view of area B of FIG. 4 according to aspects of the present disclosure;

FIG. 12 is an example cross-sectional view taken along line IV-IV′ in FIG. 11 according to aspects of the present disclosure;

FIG. 13 is another example enlarged view of area B of FIG. 4 according to aspects of the present disclosure; and

FIG. 14 is an example cross-sectional view taken along line V-V′ in FIG. 13 according to aspects of the present disclosure.

### DETAILED DESCRIPTION OF THE EMBODIMENTS

Reference will now be made in detail to example embodiments of the present disclosure, examples or aspects of which can be illustrated in the accompanying drawings. In the following description, the structures, implementations, methods, and operations described herein are not limited to the specific examples, aspects, and embodiments set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Advantages and features of the present disclosure, and implementation methods thereof will be clarified through following example embodiments described with reference to the accompanying drawings. The present disclosure can, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “contacts,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “contact,” “overlap with,” or the like each other via a fourth element. Here, the second element can be included in at least one of two or more elements that “are connected or coupled to,” “contact,” “overlap with,” or the like each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that can be caused by various factors (e.g., process factors, internal or external impact, noise, and the like) even when a relevant description is not specified. Further, the term “can” fully encompasses all the meanings of the term “can.”

In the following description, various example aspects of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, aspects of the present disclosure are not limited to a scale, dimension, size, and thickness illustrated in the drawings.

The features of various embodiments of the present disclosure can be partially or entirely coupled to or combined with each other and can be interlocked and operated in technically various ways, and the embodiments can be carried out independently of or in association with each other. Also, the term “can” used herein includes all meanings and definitions of the term “may.”

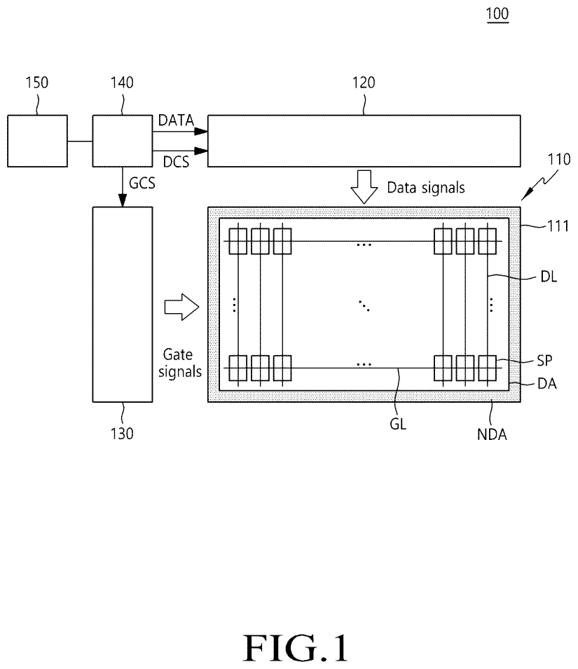

FIG. 1 illustrates an example system configuration of a display device 100 according to aspects of the present disclosure.

Referring to FIG. 1, in one or more example embodiments, the display device 100 can include a display panel 110 and at least one display driving circuit, as elements for display images. The at least one display driving circuit can be a circuit for driving the display panel 110, and include a data driving circuit 120, a gate driving circuit 130, a controller 140, and other circuit components.

The display panel 110 can include a substrate 111 and a plurality of subpixels SP disposed on the substrate 111.

The substrate 111 can include a display area DA allowing an image to be displayed and a non-display area NDA around an outer edge of the display area DA.

The display area DA can also be referred to as an active area, and a plurality of subpixels SP for displaying images can be disposed in the display area DA. The non-display area NDA can also be referred to as a non-active area and include a pad area PA.

In one or more aspects, the display panel 110 can be configured to have a very small non-display area NDA. The non-display area NDA can be also referred to as a “bezel” or “bezel area.” For example, the non-display area NDA can include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction. Herein, the first direction and the second direction can be directions perpendicular to each other on a plane.

The first non-display area among the first to fourth non-display areas can include a pad area to which one or more driving circuits are connected or bonded. Among the first to fourth non-display areas, the second to fourth non-display areas can have a very small size compared to the first non-display area.

In one or more aspects, a boundary area can be defined between the display area DA and the non-display area NDA. For example, the boundary area can be bent at a certain angle relative to the display area DA, and thereby, at least a portion of the non-display area NDA can be located under or behind the display area DA. In this implementation, when a user views the display device 100 in front thereof, all or most of the non-display area NDA can be invisible to or hidden from the user. For example, the first non-display area can include a bending area. As the bending area is bent, the first non-display area can be invisible in front of the display device 100.

Several types of signal lines for driving a plurality of subpixels SP can be disposed on the substrate 111 of the display panel 110.

In one or more aspects, the display device 100 herein can be a liquid crystal display device, or the like, or a self-emissive display device in which light is emitted from the display panel 110 itself. In an example where the display device 100 is the self-emissive display device, each of the plurality of subpixels SP can include a light emitting element.

For example, the display device 100 according to aspects of the present disclosure can be an organic light emitting display device in which light emitting elements are implemented using organic light emitting diodes (OLED). In another example, the display device 100 according to aspects of the present disclosure can be an inorganic light emitting display device in which light emitting elements are implemented using inorganic material-based light emitting diodes. In another example, the display apparatus 100 according to aspects of the present disclosure can be a quantum dot display apparatus in which the light emitting element is implemented using quantum dots, which are self-emission semiconductor crystals. But aspects of the present disclosure are not limited thereto.

The structure of each or at least one of a plurality of subpixels SP included in the display device 100 can depend on types of the display device 100. For example, when the display device 100 is a self-emissive display device including self-emissive subpixels SP, each subpixel SP can include a self-emissive light emitting element, one or more transistors, and one or more capacitors.

The several types of signal lines can include, for example, a plurality of data lines DL for carrying data signals (which can be referred to as data voltages or image signals), a plurality of gate lines GL for carrying gate signals (which can be referred to as scan signals), and the like.

For example, the plurality of data lines DL and the plurality of gate lines GL can intersect one another. Each of the plurality of data lines DL can be configured to extend in a first direction, and each of the plurality of gate lines GL can be configured to extend in a second direction. For example, the first direction can be the column direction, and the second direction can be the row direction. In another example, the first direction can be the row direction, and the second direction can be the column direction. Hereinafter, for merely convenience of explanation, discussions are provided based on examples where the first direction is the column direction and the second direction is the row direction. Hereinafter, for convenience of explanation, discussions can be provided based on examples where each of a plurality of data lines DL is disposed in the column direction, and each of a plurality of gate lines GL is disposed in the row direction, but aspects of the present disclosure are limited thereto.

The data driving circuit 120 can be a circuit configured to drive a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

For example, the data driving circuit 120 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more aspects, the data driving circuit 120 can be disposed in, and/or electrically connected to, but not limited to, only one side or edge (e.g., an upper portion or a lower portion) of the display panel 110. In one or more aspects, the data driving circuit 120 can be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 can be connected to an area outward from the display area DA of the display panel 110, or be disposed in the display area DA of the display panel 110.

The gate driving circuit 130 can be a circuit configured to drive a plurality of gate lines GL and can output gate signals to the plurality of gate lines GL.

The gate driving circuit 130 can receive several types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 can be embedded into the display panel 110 by a gate-in-panel (GIP) technique. In an example where the gate driving circuit 130 is implemented by the gate-in-panel (GIP) technique, the gate driving circuit 130 can be disposed on the substrate 111 of the display panel 110 during the manufacturing process of the display panel 110 or display device 100.

In one or more aspects, the gate driving circuit 130 can be disposed in the non-display area NDA of the display panel 110.

In one or more aspects, the gate driving circuit 130 can be disposed in the display area DA of the display panel 110. In this implementation, for example, the gate driving circuit 130 can be disposed in, and/or electrically connected to, but not limited to, a first area (e.g., a left area or a right area) of the display area DA of the display panel 110. In one or more aspects, the gate driving circuit 130 can be disposed in, and/or electrically connected to, but not limited to, a first area (e.g., a left area or a right area) of the display area DA and a second area (e.g., the right area or the left area) of the display area DA.

Herein, the gate driving circuit 130 embedded in the display panel 110 by the gate-in-panel (GIP) technique can also be referred to as a “gate-in-panel circuit.”

The controller 140 can be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 can be implemented in a separate component from the data driving circuit 120, or integrated with the data driving circuit 120, so that the controller 140 and the data driving circuit 120 can be implemented in a single integrated circuit.

The controller 140 can be a timing controller used in the display technology or a control apparatus/device capable of additionally performing other control functionalities in addition to the function of the timing controller. In one or more embodiments, the controller 140 can be one or more other control circuits different from the timing controller, or a circuit or component in the control apparatus/device. The controller 140 can be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 can be mounted on a printed circuit board, a flexible printed circuit, or the like, and can be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 can include a touch sensor, and a touch sensing circuit configured to sense the touch sensor and detect whether a touch is applied by an object such as a finger, a pen, or the like, or a location of the touch (or touch coordinates).

The touch sensing circuit can include a touch driving circuit configured to drive and sense the touch sensor and generate and output touch sensing data, and a touch controller configured to detect whether a touch is applied or a location of the touch (or touch coordinates) based on the touch sensing data.

The touch sensor can include a plurality of touch electrodes. The touch sensor can further include a plurality of touch lines for electrically connecting the plurality of touch electrodes to the touch driving circuit.

The touch sensor can be disposed outside of the display panel 110 in the form of a touch panel or can be disposed inside of the display panel 110. The touch sensor disposed outside of the display panel 110 can be referred to as an add-on type of touch sensor. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes can be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display device 100 can further include a power supply circuit configured to supply various types of power (e.g., voltages or currents) to the display driving circuit and/or the touch sensing circuit.

In one or more aspects, the display device 100 can be a mobile terminal such as a smart phone, a tablet, or the like, or a monitor, a television (TV), or the like. Further, the display device 100 can be configured with various types, sizes, and shapes to display information or images. For example, the display device 100 can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more aspects, the display device 100 can further include an electronic device such as a camera (e.g., an image sensor), an electronic unit or device such as a sensor capable of detecting an object, ambient light, etc., and the like. For example, the sensor can be a sensor capable of detecting an object or a human body by receiving light such as infrared light, ultrasonic light, ultraviolet light or the like.

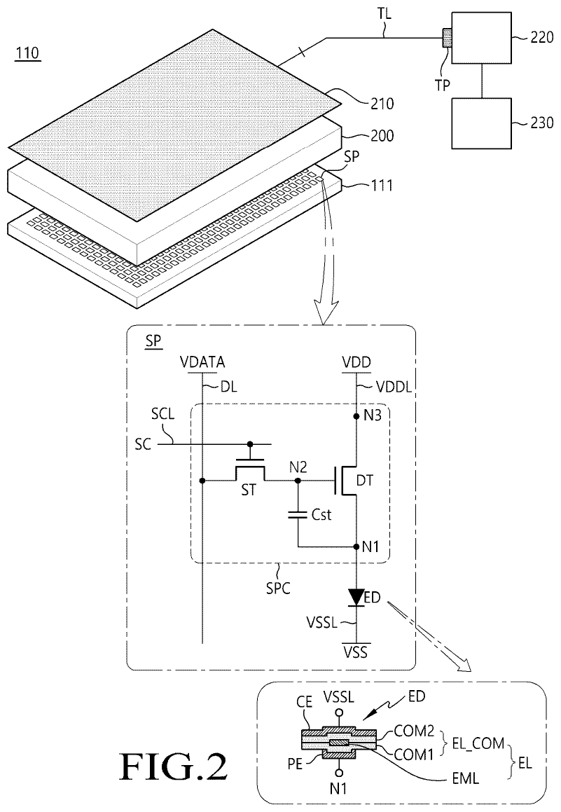

FIG. 2 illustrates an example configuration of the display panel 110 according to aspects of the present disclosure. In discussions that follow for the configuration of FIG. 2, discussions for features and examples equal, substantially equal, or similar to the features and examples described with reference to FIG. 1 are omitted or briefly described for convenience of description.

Referring to FIG. 2, in one or more example embodiments, the display panel 110 can include a substrate 111 on which a plurality of subpixels SP are disposed, and an encapsulation layer 200 over the substrate 111. The encapsulation layer 200 can also be referred to as an encapsulation substrate, an encapsulation part, or the like.

Referring to FIG. 2, in an example where the display device 100 is a self-emissive display device, each of the plurality of subpixels SP disposed on the substrate 111 can include a light emitting element ED and a subpixel circuit SPC for driving the light emitting element ED.

Referring to FIG. 2, the subpixel circuit SPC can include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors can include a driving transistor DT configured to drive the light emitting element ED and a scan transistor ST configured to be turned on or off by a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, can be applied to the at least one subpixel SP. Further, to drive one or more subpixels SP, at least one common driving voltage including a first common driving voltage VDD and a second common driving voltage VSS can be applied to the one or more subpixels SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed in each subpixel SP, and the common electrode CE can be an electrode disposed commonly in all or some of a plurality of subpixels SP. For example, the pixel electrode PE can be an anode electrode, and the common electrode CE can be a cathode electrode. In another example, the pixel electrode PE can be a cathode electrode, and the common electrode CE can be an anode electrode. Hereinafter, for convenience of explanation, discussions can be provided based on examples where the pixel electrode PE is an anode electrode, and the common electrode CE is a cathode electrode.

In an example where the light emitting element ED is an organic light emitting diode, the intermediate layer EL can include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 can be referred to as a common intermediate layer EL_COM.

For example, the emission layer EML can be disposed for each subpixel SP, and the common intermediate layer EL_COM can be commonly disposed across all or some of a plurality of subpixels SP.

For example, the emission layer EML can be disposed for each light emitting area, and the common intermediate layer EL_COM can be commonly disposed across a plurality of light emitting areas and a non-light emitting area (e.g., laid down as a common layer).

For example, the emission layer EML and the common intermediate layer EL_COM can be commonly disposed across all or some of a plurality of subpixels SP.

For example, the emission layer EML and the common intermediate layer EL_COM can be commonly disposed across a plurality of light emitting areas and a non-light emitting area.

For example, the first common intermediate layer COM1 can include a hole injection layer (HIL), a hole transfer layer (HTL), and the like. The second common intermediate layer COM2 can include an electron transport layer (ETL), an electron injection layer (EIL), and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

For example, the common electrode CE can be electrically connected to a second common driving voltage line VSSL. A second common driving voltage VSS can be applied to the common electrode CE through the second common driving voltage line VSSL. The pixel electrode PE can be electrically connected directly or indirectly (via another transistor) to a first node N1 of the corresponding driving transistor DT of each subpixel SP. Herein, the second common driving voltage VSS can also be referred to as a “base voltage,” and the second common driving voltage line VSSL can also be referred to as a “low power supply voltage line,” a “low voltage line,” or a “base voltage line.

Each light emitting element ED can be configured by overlapping of a pixel electrode PE, an emission layer EML in an intermediate layer EL, and a common electrode CE. A respective light emitting area can be formed by each light emitting element ED. For example, a respective light emitting area of each light emitting element ED can include an area where a pixel electrode PE, an emission layer EML in an intermediate layer EL, and a common electrode CE overlap with each other

In one or more aspects, each or at least one of a plurality of light emitting elements ED included in the display panel 110 or the display device 100 can be an organic light emitting diode (OLED), an inorganic light emitting diode (LED), a quantum dot (QD) light emitting element, a micro light emitting diode, a mini light emitting diode, or the like, but aspects of the present disclosure are not limited thereto. In the example where each light emitting element ED is an organic light emitting diode (OLED), the intermediate layer EL of a corresponding light emitting element ED can be a layer including an organic material.

The driving transistor DT can be a transistor configured to supply a driving current to the light emitting element ED. The driving transistor DT can be connected between a first common driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. A first common driving voltage VDD delivered through the first common driving voltage line VDDL can be applied to the third node N3.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes (or electrodes), respectively. However, aspects of the present disclosure are not limited thereto.

The scan transistor ST included in the subpixel circuit SPC illustrated in FIG. 2 can be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed to be located outside of the driving transistor DT, and therefore, be different from an internal capacitor such as a parasitic capacitor (e.g., a Cgs, a Cgd) that can be formed between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

The subpixel circuit SPC can have a 2T(Transistor)1C(Capacitor) structure including two transistors (DT and ST) and one capacitor (Cst) as illustrated in FIG. 2. In one or more aspects, the subpixel circuit SPC can further include one or more transistors or one or more capacitors in the 2T1C structure.

For example, the subpixel circuit SPC can have an 8T1C structure including 8 transistors and 1 capacitor. In another example, the subpixel circuit SPC can have an 6T2C structure including 6 transistors and 2 capacitor. In another example, the subpixel circuit SPC can have an 7T1C structure including 7 transistors and 1 capacitor. However, aspects of the present disclosure are not limited to such specific structures.

The types and number of gate signals supplied to a subpixel SP, and/or the types and number of gate lines connected to the subpixel SP can vary depending on a structure of a corresponding subpixel circuit SPC. Further, the types and number of common driving voltages supplied to a subpixel SP can vary depending on a structure of a corresponding subpixel circuit SPC.

Referring to FIG. 2, since circuit elements (e.g., a light emitting element ED such as an organic light emitting diode (OLED) including an organic material) in each subpixel SP can be easily damaged by external moisture or oxygen, an encapsulation layer 200 can be disposed in the display panel 110 to prevent the external moisture or oxygen from penetrating the circuit elements (e.g., the light emitting element ED).

The encapsulation layer 200 can be disposed in various shapes or configurations to prevent light emitting elements ED from contacting moisture or oxygen. For example, the encapsulation layer 200 can include two or more layers in which one or more organic layers and one or more inorganic layers are alternately stacked, but aspects of the present disclosure are not limited thereto.

Referring to FIG. 2, in one or more aspects, to sense a touch of a user, the display device 100 can include a touch sensor layer 210 including a plurality of sensor electrodes, a touch driving circuit 220 configured to sense the plurality of sensor electrodes, and a touch controller 230 configured to determine whether a touch is applied or a location of the touch (e.g., touch coordinates) based on the sensing result (e.g., touch sensing data) of the touch driving circuit 220.

The touch sensor layer 210 can be embedded in the display panel 110. For example, the touch sensor layer 210 can be disposed on the encapsulation layer 200 of the display panel 110.

The display panel 110 can include a plurality of touch pads TP to which the touch driving circuit 220 is electrically connected, and a plurality of touch lines for electrically connecting the plurality of sensor electrodes included in the touch sensor layer 210 to the plurality of touch pads TP to which the touch driving circuit 220 is connected.

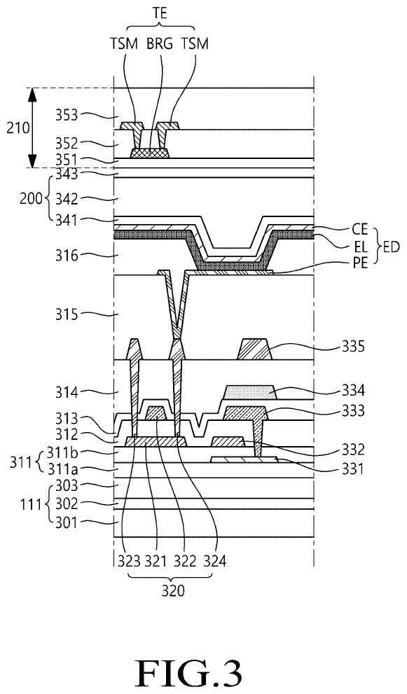

FIG. 3 is an example cross-sectional view of a subpixel SP included in the display device 100 according to aspects of the present disclosure. In discussions that follow for the configuration of FIG. 3, discussions for features and examples equal, substantially equal, or similar to the features and examples described with reference to FIGS. 1 and 2 are omitted or briefly described for convenience of description.

Referring to FIG. 3, in one or more example embodiments, the display panel 110 can include a transistor part, a light emitting element part, an encapsulation part, and a touch sensor part in terms of stack-up structure.

The substrate 111 can include a single layer or a multilayer. The substrate 111 can include a glass or plastic material. The substrate 111 can have a flexible characteristic. When the substrate 111 includes a multilayer, the substrate 111 can include a first substrate 301, a substrate intermediate layer 302, and a second substrate 303. The substrate intermediate layer 302 can be located between the first substrate 301 and the second substrate 303. For example, each of the first substrate 301 and the second substrate 303 can be a polyimide (PI) layer. The substrate intermediate layer 302 can be an inorganic insulating layer. When charges are stored in the first substrate 301, which is the polyimide layer, the substrate intermediate layer 302 can block the charges from affecting one or more transistors disposed on the second substrate 303 through the second substrate 303, which is the polyimide layer.

In addition, the substrate intermediate layer 302 can block moisture from penetrating upwardly through the first substrate 301. For example, the substrate intermediate layer 302 can be in the form of a single layer of silicon nitride (SiNx) or silicon oxide (SiOx), a multilayer of silicon nitride (SiNx), silicon oxide (SiOx), and/or the like, or a double layer of silicon oxide (SiOx) and silicon nitride (SiNx). However, aspects of the present disclosure are not limited thereto.

The transistor part can include the substrate 111, and several types of insulating layers (311, 312, 313, and 314), at least one transistor 320, at least one storage capacitor Cst, and various electrodes or signal lines, which are disposed on the substrate 111.

Referring to FIG. 3, a buffer layer 311 can be disposed on the substrate 111. The buffer layer 311 can be in the form of a single layer or multilayer. In an example where the buffer layer 311 is in the form of a multilayer, the buffer layer 311 can include a multi-buffer layer 311a and an active buffer layer 311b.

The multi-buffer layer 311a can be an inorganic insulating layer. The multi-buffer layer 311a can block or delay the diffusion of moisture or oxygen penetrating the substrate 111. For example, the multi-buffer layer 311a can be in the form of a single layer of silicon nitride (SiNx), silicon oxide (SiOx), or silicon oxynitride (SiOxNy), or a multilayer of silicon nitride (SiNx), silicon oxide (SiOx), and/or silicon oxynitride (SiOxNy), but aspects of the present disclosure are not limited thereto.

The active buffer layer 311b can be an inorganic insulating layer. The active buffer layer 311b can protect an active layer 321 of the transistor 320 and can serve to block or delay various types of defects reaching, or occurring in, the substrate 111. For example, the active buffer layer 311b can be in the form of a single layer of amorphous silicon (a-Si), silicon nitride (SiNx), or silicon oxide (SiOx), or a multilayer of amorphous silicon (a-Si), silicon nitride (SiNx), and/or silicon oxide (SiOx), but aspects of the present disclosure are not limited thereto.

A shield metal 331 (e.g., light shielding layer) can be disposed between the multi-buffer layer 311a and the active buffer layer 311b. The shield metal 331 can serve as a display signal line or a portion of the storage capacitor Cst disposed in a subpixel SP. According to an embodiment, the shield metal 331 can provide dual functions of blocking light and carrying a signal or blocking light and storing a capacitance charge.

The active layer 321 of the transistor 320 can be disposed on the buffer layer 311. The active layer 321 can be disposed on the active buffer layer 311b. The active layer 321 can include a channel region where a channel is formed, a source connection region on one side of the channel region, and a drain connection region on the other side of the channel region. The active layer 321 can include a semiconductor material, but aspects of the present disclosure are not limited thereto. For example, the active layer 321 can include oxide semiconductor, amorphous silicon, polysilicon, or low-temperature polysilicon (LTPS), but aspects of the present disclosure are not limited thereto. The transistor 320 can be a p-type transistor or an n-type transistor, but aspects of the present disclosure are not limited thereto. In one or more aspects, the active layer 332 can become conductive and serve as a portion of a display signal line or the storage capacitor Cst.

A gate insulating layer 312 can be disposed on the active layer 321 of the transistor 320. The gate insulating layer 312 can be in the form of a single layer of silicon nitride (SiNx) or silicon oxide (SiOx), or a multilayer of silicon nitride (SiNx), silicon oxide (SiOx), and/or the like, but aspects of the present disclosure are not limited thereto.

A gate metal layer can be disposed on the gate insulating layer 312. For example, a gate metal layer 322 can serve as a first electrode 322 of the transistor 320. For example, a gate metal layer 333 can serve as a portion of a display signal line or the storage capacitor Cst. The first electrode 322 of the transistor (320) can be the gate electrode 322 of the transistor 320. The gate metal layer can be in the form of a single layer of one of molybdenum (Mo), copper (Cu), titanium (Ti), aluminum (Al), chromium (Cr), gold (Au), nickel (Ni), neodymium (Nd), tungsten (W), or an alloy of two or more of molybdenum (Mo), copper (Cu), titanium (Ti), aluminum (Al), chromium (Cr), gold (Au), nickel (Ni), neodymium (Nd), and/or tungsten (W), or a multilayer of one or more of molybdenum (Mo), copper (Cu), titanium (Ti), aluminum (Al), chromium (Cr), gold (Au), nickel (Ni), neodymium (Nd), tungsten (W), and/or one or more alloys of two or more of molybdenum (Mo), copper (Cu), titanium (Ti), aluminum (Al), chromium (Cr), gold (Au), nickel (Ni), neodymium (Nd), and/or tungsten (W). However, aspects of the present disclosure are not limited thereto.

A first interlayer insulating layer 313 can be disposed on the gate electrode 322 of the transistor 320. The first interlayer insulating layer 313 can be in the form of a single layer of silicon nitride (SiNx) or silicon oxide (SiOx), or a multilayer of silicon nitride (SiNx), silicon oxide (SiOx), and/or the like, but aspects of the present disclosure are not limited thereto.

An auxiliary electrode layer 334 can be disposed on the first interlayer insulating layer 313. The auxiliary electrode layer 334 can be used variously. For example, the auxiliary electrode layer 334 can serve as a portion of a display signal line or the storage capacitor Cst, or the like.

A second interlayer insulating layer 314 can be disposed on the auxiliary electrode layer 334 and the first interlayer insulating layer 313. The second interlayer insulating layer 314 can be in the form of a single layer of silicon nitride (SiNx) or silicon oxide (SiOx), or a multilayer of silicon nitride (SiNx), silicon oxide (SiOx), and/or the like, but aspects of the present disclosure are not limited thereto.

A source-drain metal layer can be disposed on the second interlayer insulating layer 314. The source-drain metal layers (323 and 324) can serve as a second electrode 323 and a third electrode 324 of the transistor 320. For example, a source-drain metal layer 335 can serve as a display signal line, or the like. The second electrode 323 of the transistor 320 can be a source electrode or a drain electrode, and the third electrode 324 of the transistor 320 can be the drain electrode or the source electrode. Hereinafter, for convenience of explanation, the second electrode 323 can be referred to as the drain electrode 323 and the third electrode 324 can be referred to as the source electrode 324. However, aspects of the present disclosure are not limited thereto. The source-drain metal layer can be in the form of a single layer of one of molybdenum (Mo), copper (Cu), titanium (Ti), aluminum (Al), chromium (Cr), gold (Au), nickel (Ni), neodymium (Nd), tungsten (W), or an alloy of two or more of molybdenum (Mo), copper (Cu), titanium (Ti), aluminum (Al), chromium (Cr), gold (Au), nickel (Ni), neodymium (Nd), and/or tungsten (W), or a multilayer of one or more of molybdenum (Mo), copper (Cu), titanium (Ti), aluminum (Al), chromium (Cr), gold (Au), nickel (Ni), neodymium (Nd), tungsten (W), and/or one or more alloys of two or more of molybdenum (Mo), copper (Cu), titanium (Ti), aluminum (Al), chromium (Cr), gold (Au), nickel (Ni), neodymium (Nd), and/or tungsten (W). However, aspects of the present disclosure are not limited thereto.

The drain electrode 323 and the source electrode 324 of the transistor 320 can be electrically connected to the drain connection region and the source connection region of the active layer 321, respectively, through contact holes of the gate insulating layer 312, the first interlayer insulating layer 313, and the second interlayer insulating layer 314.

Referring to FIG. 3, a planarization layer 315 can be disposed on the source-drain metal layer and the second interlayer insulating layer 314. The planarization layer 315 can be in the form of a single layer or a multilayer of two or more layers. The planarization layer 315 can be an organic insulating layer capable of performing a flattening function.

The planarization layer 315 can be disposed on the drain electrode 323 and the source electrode 324 of the transistor 320. For example, the planarization layer 315 can be disposed such that it covers all of the transistor 320. The planarization layer 315 can be an organic insulating layer for flattening and protecting an upper portion of the transistor 320. For example, the planarization layer 315 can include an organic insulating material such as an acrylic resin, an epoxy resin, a phenolic resin, a polyamide resin, a polyimide resin, a polyethylene resin, silicon oxycarbon (SiOCx), or the like, but aspects of the present disclosure are not limited thereto. In one or more aspects, the planarization layer 315 can include a thermosetting material or a photocurable material that can be cured by heat or light. The planarization layer 315 can serve to alleviate or eliminate a step difference between layers or edges of various components such as the transistor 320, the storage capacitor Cst, various signal lines, and the like disposed in an area where each subpixel SP is disposed.

Referring to FIG. 3, the light emitting element part can be disposed on the planarization layer 315. A light emitting element ED can be disposed on the planarization layer 315. The light emitting element ED can include a pixel electrode PE, an intermediate layer EL, and a common electrode CE. A light emitting area of the light emitting element ED can be formed in an area where the pixel electrode PE, the intermediate layer EL, and the common electrode CE overlap and contact each other.

The pixel electrode PE can be disposed on the planarization layer 315. The pixel electrode PE can be electrically connected to the source electrode 324 through a contact hole of the planarization layer 315.

A bank 316 can be disposed on the pixel electrode PE. An opening (open portion) of the bank 316 can expose a portion of the pixel electrode PE to form the light emitting area. For example, the opening of the bank 316 can overlap with the portion of the pixel electrode PE. The bank 316 can include, but is not limited to, an inorganic insulating material such as silicon nitride (SiNx) or silicon oxide (SiOx), or an organic insulating material such as a benzocyclobutene-based resin, an acrylic-based resin, or an imide-based resin. In one or more aspects, a spacer can be disposed on the bank 316.

The intermediate layer EL of the light emitting element ED can be disposed on a portion of the pixel electrode PE and the bank 316. The common electrode CE can be disposed on the intermediate layer EL.

Referring to FIG. 3, the encapsulation part can be disposed on the light emitting element part, and be disposed on the common electrode CE. The encapsulation part can include an encapsulation layer 200 disposed on the common electrode CE. A bottom surface of the encapsulation layer 200 can directly contact an upper surface of the common electrode CE, but embodiments are not limited thereto.

The encapsulation layer 200 can prevent moisture or oxygen from penetrating the light emitting element ED. For example, the encapsulation layer 200 can prevent moisture or oxygen from penetrating an organic material contained in the intermediate layer EL of the light emitting element ED. For example, the encapsulation layer 200 can be in the form of a single layer or multilayer, but aspects of the present disclosure are not limited thereto.

Referring to FIG. 3, for example, the encapsulation layer 200 can include a first encapsulation layer 341, a second encapsulation layer 342, and a third encapsulation layer 343. The first encapsulation layer 341 and the third encapsulation layer 343 can include, for example, an inorganic layer, and the second encapsulation layer 342 can include, for example, an organic layer.

The first encapsulation layer 341 can be disposed on the common electrode CE and can be disposed closest to the light emitting element ED. The first encapsulating layer 341 can include an inorganic insulating material that can be deposited at a low temperature. For example, the first encapsulation layer 341 can include silicon nitride (SiNx), silicon oxide (SiOx), silicon oxynitride (SiOxNy), aluminum oxide (AlOx), or the like. As the first encapsulation layer 341 is deposited in a low temperature atmosphere, the intermediate layer EL containing an organic material vulnerable to a high temperature atmosphere can be prevented from being damaged during the deposition process.

The second encapsulation layer 342 can cover or block undesired substances or particles that can occur during the manufacturing process. The second encapsulation layer 342 can flatten or planarize the surface of the first encapsulation layer 341. For example, the second encapsulation layer 342 can be referred to as a particle cover layer PCL, but aspects of the present disclosure are not limited thereto. The second encapsulation layer 342 can serve as a buffer to relieve stress between layers in a situation where the display device 100 bent and also serve to enhance flattening performance.

For example, the second encapsulation layer 342 can have a smaller area than the first encapsulation layer 341. In this example, the second encapsulation layer 342 can be disposed such that it exposes both ends of the first encapsulation layer 341. For example, an outer edge of the second encapsulation layer 342 can be sealed by the first encapsulation layer 341 and the third encapsulation layer 343, but embodiments are not limited thereto.

The second encapsulation layer 342 can include an organic insulating material such as an acrylic resin, an epoxy resin, a phenol resin, a polyamide resin, a polyimide resin, a polyethylene resin, silicon oxycarbon (SiOCx), or the like, but aspects of the present disclosure are not limited thereto. In one or more aspects, the second encapsulation layer 342 can include a thermosetting material or a photocurable material that can be cured by heat or light.

The second encapsulation layer 342 can be formed in various processes such as inkjet coating, slit coating, and the like. For example, the second encapsulation layer 342 can be formed on the first encapsulation layer 341 by spraying or dropping a liquid organic material onto the display area DA using an inkjet device or a nozzle coating device on the substrate 111 on which the first encapsulation layer 341 is disposed. However, aspects of the present disclosure are not limited thereto.

The third encapsulation layer 343 can be disposed on the substrate 111 on which the second encapsulation layer 342 is disposed such that the third encapsulation layer 343 covers an upper surface and at least one side surface of each of the second encapsulation layer 342 and the first encapsulation layer 341. In this configuration, the third encapsulation layer 343 can minimize or block external moisture or oxygen from penetrating the first encapsulation layer 341 and the second encapsulation layer 342. For example, the third encapsulation layer 343 can include an inorganic insulating material such as silicon nitride (SiNx), silicon oxide (SiOx), silicon oxynitride (SiOxNy), aluminum oxide (AlOx), or the like, but aspects of the present disclosure are not limited thereto.

In one or more aspects, a touch sensor can be embedded in the display panel 110. Referring to FIG. 3, the touch sensor part can be disposed on the encapsulation part and be located on the common electrode CE. The touch sensor part can include a touch sensor layer 210 disposed on the encapsulation layer 200.

Referring to FIG. 3, the touch sensor layer 210 can include a plurality of touch electrodes TE, and include sensor metals TSM and bridge metals BRG to form the plurality of touch electrodes TE. Herein, the sensor metals TSM can be also referred to as a sensor metal layer TSM, and the bridge metals BRG can be also referred to as a bridge metal layer BRG.

The touch sensor layer 210 can further include one or more insulating layers such as a sensor buffer layer 351 on the encapsulation layer 200, a sensor interlayer insulating layer 352 on the sensor buffer layer 351, a sensor protection layer 353 on the sensor interlayer insulating layer 352, and/or the like. In one or more aspects, the sensor buffer layer 351 can be omitted.

The bridge metals BRG can be disposed between the sensor buffer layer 351 and the sensor interlayer insulating layer 352, and the sensor metals TSM can be disposed between the sensor interlayer insulating layer 352 and the sensor protection layer 353.

The sensor buffer layer 351 can be disposed on the encapsulation layer 200. The sensor buffer layer 351 can prevent damage to the encapsulation layer 200 and serve to block the interference of a signal of the transistor 320 with one or more touch electrodes TE. The sensor buffer layer 351 can facilitate the formation of the touch electrode TE on the encapsulation layer 200, and improve an adhesion between touch electrodes TE and the encapsulation layer 200. The sensor buffer layer 351 can prevent a defect in which sensor metals and/or bridge metals disposed on the sensor buffer layer 351 are disconnected (or separated) due to external impact. The sensor buffer layer 351 can be an inorganic insulating layer. For example, the sensor buffer layer 351 can include an inorganic insulating material such as silicon oxide (SiOx), silicon nitride (SiNX), silicon oxide nitride (SiOxNy), or the like, and be in the form of a single layer or multilayer. However, aspects of the present disclosure are not limited thereto.

Each of the plurality of touch electrodes TE can be formed by using one sensor metal TSM or two or more sensor metals TSM. In this implementation, each of the plurality of touch electrodes TE can be a mesh-type touch electrode with a plurality of openings.

The plurality of touch electrodes TE can include first touch electrodes TE1 and second touch electrodes TE2. Two or more sensor metals TSM, or two or more parts of one sensor metal TSM, included in each first touch electrode TE1 or each second touch electrode TE2 can be electrically connected through one or more bridge metals BRG. For example, sensor metals TSM or two or more parts of one sensor metal TSM, which are spaced apart from each other, can be electrically connected by one or more bridge metals BRG, and thereby, one first touch electrode TE1 or one second touch electrode TE2 can be formed.

The bridge metals BRG can be disposed on the sensor buffer layer 351, and the sensor interlayer insulating layer 352 can be disposed on the bridge metal layer BRG. The sensor interlayer insulating layer 352 can serve to electrically insulate the bridge metal layer BRG and the sensor metal layer TSM from each other. The sensor interlayer insulating layer 352 can include contact holes for electrically connecting one or more bridge metals BRG and one or more sensor metals TSM to each other. A thickness of the sensor interlayer insulating layer 352 can be greater than a thickness of the sensor buffer layer 351.

The sensor interlayer insulating layer 352 can be formed to have a sufficient thickness so that a residual film cannot be formed due to a step difference between layers or edges during the manufacturing process. The sensor interlayer insulating layer 352 can include an inorganic insulating material or an organic insulating material. For example, the sensor interlayer insulating layer 352 can include an inorganic insulating material such as silicon oxide (SiOx), silicon nitride (SiNX), silicon oxide nitride (SiOxNy), or the like, and be in the form of a single layer or multilayer. However, aspects of the present disclosure are not limited thereto. In another example, the sensor interlayer insulating layer 352 can include an organic insulating material such as an acrylic resin, an epoxy resin, a phenol resin, a polyamide resin, a polyimide resin, a polyethylene resin, silicon oxycarbon (SiOCx), or the like, but aspects of the present disclosure are not limited thereto. In one or more aspects, the sensor interlayer insulating layer 352 can include a thermosetting material or a photocurable material that can be cured by heat or light.

The sensor metals TSM can be disposed on the sensor interlayer insulating layer 352. In one or more aspects, one or more of the sensor metals TSM or one or more of parts of one sensor metal TSM can be electrically connected to one or more bridge metals BRG through one or more contact holes of the sensor interlayer insulating layer 352.

Referring to FIG. 3, the sensor metals TSM or the parts of one sensor metal TSM and the bridge metal BRG can be disposed not to overlap with the light emitting element ED. The sensor metals TSM or the parts of one sensor metal TSM and the bridge metal BRG can overlap with the bank 334.

In one or more aspects, a plurality of sensor metals TSM can be included in one touch electrode TE, be mesh-type touch electrodes, and be electrically connected to each other. One or more of the sensor metals TSM and other one or more of the sensor metals TSM can be electrically connected through one or more bridge metals BRG, and thereby form one touch electrode TE.

The sensor protection layer 353 can be disposed such that it covers the sensor metals TSM and the bridge metals BRG. The sensor protection layer 353 can include an organic insulating material. The organic insulating material can be, for example, the same material as the material included in the planarization layer 315 and the second encapsulation layer 342. In one or more aspects, the organic insulating material can include a different material from the planarization layer 315 and the second encapsulation layer 342. For example, the sensor protection layer 353 can include an organic insulating material such as an acrylic resin, an epoxy resin, a phenol resin, a polyamide resin, a polyimide resin, a polyethylene resin, silicon oxycarbon (SiOCx), or the like, but aspects of the present disclosure are not limited thereto. In one or more aspects, the sensor protection layer 353 can include a thermosetting material or a photocurable material that can be cured by heat or light.

In one or more aspects, the display panel 110 can also include color filters. In this implementation, the display panel 110 can include a color filter layer disposed on the encapsulation layer 200. The display panel 110 can include a color filter buffer layer and the color filters, which are disposed on the touch sensor layer 210.

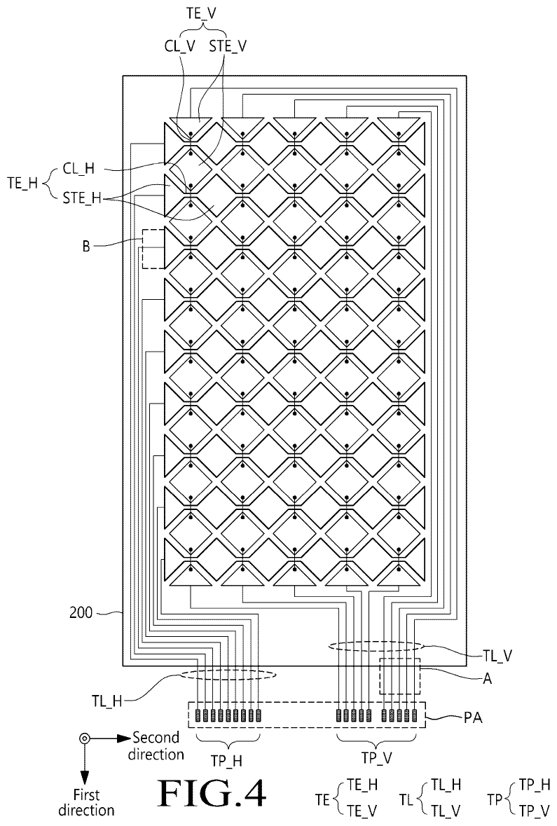

FIG. 4 illustrates an example touch sensor structure included in the display device 100 to aspects of the present disclosure. In discussions that follow for the configuration of FIG. 4, discussions for features and configurations equal, substantially equal, or similar to the features and configurations described with reference to FIGS. 1 to 3 are omitted or briefly described for convenience of description..

Referring to FIG. 4, in one or more example embodiments, a touch sensor included in the display device 100 can include a plurality of touch electrodes TE. The plurality of touch electrodes TE can include a plurality of horizontal touch electrodes TE_H and a plurality of vertical touch electrodes TE_V.

The plurality of touch electrodes TE can be located in the display area DA and be disposed on the encapsulation layer 200.

Each of the plurality of horizontal touch electrodes TE_H can include two or more horizontal sub-touch electrodes STE_H disposed in the same row (or column) and one or more horizontal bridge electrodes CL_H electrically connecting the two or more horizontal sub-touch electrodes STE_H to each other. For example, as in the example of FIG. 4, two or more horizontal sub-touch electrodes STE_H and one or more horizontal bridge electrodes CL_H included in one horizontal touch electrode TE_H can be an integrally formed touch metal (e.g., a second touch metal). In another example, as in the example of FIG. 4, two or more horizontal sub-touch electrodes STE_H can be disposed in a second touch metal layer, and one or more horizontal bridge electrodes CL_H can be disposed in a first touch metal layer.

Each of the plurality of vertical touch electrodes TE_V can include two or more vertical sub-touch electrodes STE_V disposed in the same column (or row) and one or more vertical bridge electrodes CL_V electrically connecting the two or more vertical sub-touch electrodes STE_V to each other. For example, two or more vertical sub-touch electrodes STE_V and one or more vertical bridge electrodes CL_V included in one vertical touch electrode TE_V can be an integrally formed touch metal (e.g., a second touch metal). In another example, as in the example of FIG. 4, two or more vertical sub-touch electrodes STE_V can be disposed in a second touch metal layer, and one or more vertical bridge electrodes CL_V can be disposed in a first touch metal layer.

In an area where a horizontal touch electrode TE_H and a vertical touch electrode TE_V intersect each other (which can be referred to as a touch electrode intersection area), a horizontal bridge electrode CL_H and a vertical bridge electrode CL_V can intersect each other.

In the touch electrode intersection area, when the horizontal bridge electrode CL_H and the vertical bridge electrode CL_V intersect each other, the horizontal bridge electrode CL_H and the vertical bridge electrode CL_V can be needed to be located in different layers.

Accordingly, in order for the plurality of horizontal touch electrodes TE_H and the plurality of vertical touch electrodes TE_V to be disposed to intersect each other, the plurality of horizontal sub-touch electrodes STE_H, the plurality of horizontal bridge electrodes CL_H, the plurality of vertical sub-touch electrodes STE_V, and the plurality of vertical bridge electrodes CL_V can be located in two or more layers.

Referring to FIG. 4, in one or more aspects, the touch sensor structure can further include a plurality of touch routing lines TL. The plurality of touch routing lines TL can include a plurality of horizontal touch routing lines TL_H and a plurality of vertical touch routing lines TL_V.

The plurality of touch routing lines TL can be disposed in the non-display area NDA. A portion (e.g., a portion connected to a touch electrode) of at least one of the plurality of touch routing lines TL can be located in the display area DA.

In one or more aspects, the touch sensor structure can further include a plurality of touch pads TP. The plurality of touch pads TP can include a plurality of horizontal touch pads TP_H and a plurality of vertical touch pads TP_V. The plurality of touch pads TP can be disposed in the non-display area NDA. FIG. 4 illustrates that the plurality of touch pads TP are disposed at a lower edge of the display panel, which is the first non-display area, but aspects of the present disclosure are not limited thereto. For example, the plurality of touch pads TP can be disposed in the second non-display area, the third non-display area, or the fourth non-display area of the display panel.

Referring to FIG. 4, each of the plurality of horizontal touch electrodes TE_H can be electrically connected to a corresponding horizontal touch pad TP_H via one or more horizontal touch routing lines TL_H. At least one of two horizontal sub-touch electrodes STE_H disposed at the outermost sides among two or more horizontal sub-touch electrodes STE_H included in one horizontal touch electrode TE_H can be electrically connected to a corresponding horizontal touch pad TP_H via a horizontal touch routing line TL_H.

Each of the plurality of vertical touch electrodes TE_V can be electrically connected to a corresponding vertical touch pad TP_V via one or more vertical touch routing lines TL_V. For example, at least one of two vertical sub-touch electrodes STE_V disposed on the outermost sides among two or more vertical sub-touch electrodes STE_V included in one vertical touch electrode TE_V can be electrically connected to a corresponding vertical touch pad TP_V through a vertical touch routing line TL_V.

In one or more aspects, as illustrated in FIG. 4, the plurality of horizontal touch electrodes TE_H and the plurality of vertical touch electrodes TE_V can be disposed on an encapsulation layer 200. The plurality of horizontal sub-touch electrodes STE_H and the plurality of horizontal bridge electrodes CL_H included in the plurality of horizontal touch electrodes TE_H can be disposed on the encapsulation layer 200. The plurality of vertical sub-touch electrodes STE_V and the plurality of vertical bridge electrodes CL_V included in the plurality of vertical touch electrodes TE_V can be disposed on the encapsulation layer 200.

Each of the plurality of horizontal touch routing lines TL_H can be disposed on the encapsulation layer 200, extend outside of the encapsulation layer 200, and be electrically connected to a corresponding one of the plurality of horizontal touch pads TP_H in a pad area PA located in an outward area from the encapsulation layer 200.

Each of the plurality of vertical touch routing lines TL_V can be disposed on the encapsulation layer 200, extend outside of the encapsulation layer 200, and be electrically connected to a corresponding one of the plurality of vertical touch pads TP_V in a pad area PA located in an outward area from the encapsulation layer 200.

The encapsulation layer 200 can be located in the display area DA, and in one or more aspects, can be extended to the non-display area NDA.

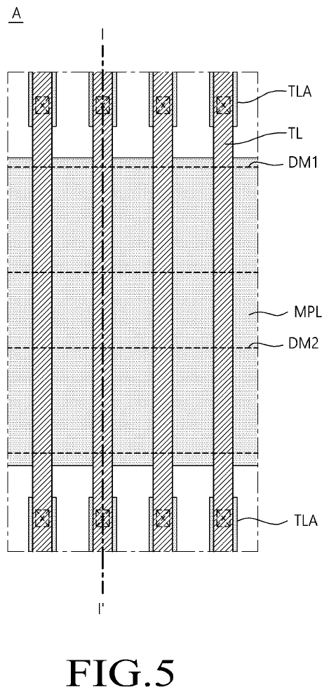

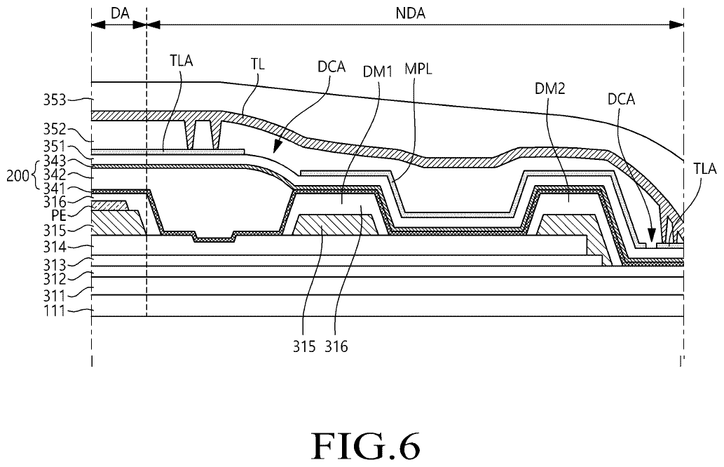

FIG. 5 is an example enlarged view of area A of FIG. 4. FIG. 6 is an example cross-sectional view taken along line I-I′ in FIG. 5. In discussions that follow for the configurations of FIGS. 5 and 6, discussions for features and examples equal, substantially equal, or similar to the features and examples described with reference to FIGS. 1 to 4 are omitted or briefly described for convenience of description.

Referring to FIGS. 3, 5 and 6, in one or more example embodiments, the display panel 110 can include the substrate 111, the insulating layers (311, 312, 313, and 314) on the substrate 111, the planarization layer 315, the pixel electrode PE, the bank 316, the encapsulation layer 200, the sensor buffer layer 351, the sensor interlayer insulating layer 352, the sensor protection layer 353, at least one touch routing line TL, at least one auxiliary routing line TLA, a moisture preventing layer MPL, and at least one dam structure DM. In discussing configurations of FIGS. 5 and 6, repeated discussions for the substrate 111, the insulating layers (311, 312, 313, and 314), the planarization layer 315, the pixel electrode PE, and the bank 316 already described with reference to FIG. 3, which are equally applied to the configurations of FIGS. 5 and 6, are omitted for conciseness.

Referring to FIGS. 5 and 6, touch routing lines TL can be disposed to extend from the display area DA to the non-display area NDA. Auxiliary routing lines TLA can be disposed to be overlapped with the touch routing lines TL in a plan view. The touch routing lines TL and the auxiliary routing lines TLA can be electrically connected to each other through contact holes.

The at least one dam structure DM can be located in an area outward from or outside of the display area DA. For example, the at least one dam structure DM can include a first dam DM1 and a second dam DM2. The first dam DM1 can be located between the display area DA and the second dam DM2. The first dam DM1 can be an inner dam, and the second dam DM2 can be an outer dam. The at least one dam structure DM can be formed using at least respective portions of layers (e.g., the planarization 315, the bank 316, and the like) disposed in the display area DA. The at least one dam structure DM can be surrounded by a portion of the encapsulation layer 200. A pad area PA can be located in an area outward from or outside of the at least one dam structure DM.

The sensor buffer layer 351 can be disposed on the encapsulation layer 200. The sensor buffer layer 351 can be disposed on the first dam DM1 and the second dam DM2. The sensor buffer layer 351 can be disposed such that it covers the first dam DM1 and the second dam DM2 and extend outwardly. For example, the sensor buffer layer 351 can extend across both of the first dam DM1 and the second dam DM2. The sensor buffer layer 351 can be an inorganic insulating layer. For example, the sensor buffer layer 351 can include an inorganic insulating material such as silicon oxide (SiOx), silicon nitride (SiNX), silicon oxide nitride (SiOxNy), or the like, and be in the form of a single layer or multilayer. However, aspects of the present disclosure are not limited thereto.

The auxiliary routing lines TLA can be disposed on the sensor buffer layer 351. The auxiliary routing lines TLA can be formed by using bridge metals BRG. The auxiliary routing lines TLA can be disposed in a disconnected (or separated) form in the non-display area NDA. For example, an auxiliary routing line TLA can be disconnected (or separated) at at least one portion of the non-display area NDA. Thereby, at least one disconnection (or separation) area TLA formed by the disconnection (or separation) of the auxiliary routing line TLA can be disposed in the non-display area NDA. The auxiliary routing lines TLA may not be disposed in an area overlapping with the at least one dam structure DM. For example, the auxiliary routing lines TLA may not be disposed on the first dam DM1, the second dam DM2, and an area between the first dam DM1 and the second dam DM2. For example, the first dam DM1 and the second dam DM2 can be disposed in a disconnected area between adjacent auxiliary routing lines TLA that are separated from each other. Also, a corresponding touch routing line TL can electrically connect adjacent auxiliary routing lines TLA that are separated from each other (e.g., in a bridge type structure), e.g., the corresponding touch routing line TL can pass over the first dam DM1 and the second dam DM2.

The sensor interlayer insulating layer 352 can be disposed on the auxiliary routing lines TLA and the sensor buffer layer 351. The sensor interlayer insulating layer 352 can serve to electrically insulate the touch routing lines TL and the auxiliary routing lines TLA from each other. The sensor interlayer insulating layer 352 can include contact holes for electrically connecting the touch routing lines TL and the auxiliary routing lines TLA to each other. A thickness of the sensor interlayer insulating layer 352 can be greater than a thickness of the sensor buffer layer 351 (e.g., thickness of 352>thickness of 351).

The sensor interlayer insulating layer 352 can be formed to have a sufficient thickness so that a residual film cannot be formed due to a step difference between layers or edges during the manufacturing process. The sensor interlayer insulating layer 352 can include an inorganic insulating material or an organic insulating material. For example, the sensor interlayer insulating layer 352 can include an inorganic insulating material such as silicon oxide (SiOx), silicon nitride (SiNX), silicon oxide nitride (SiOxNy), or the like, and be in the form of a single layer or multilayer. However, aspects of the present disclosure are not limited thereto. In another example, the sensor interlayer insulating layer 352 can include an organic insulating material such as an acrylic resin, an epoxy resin, a phenol resin, a polyamide resin, a polyimide resin, a polyethylene resin, silicon oxycarbon (SiOCx), or the like, but aspects of the present disclosure are not limited thereto. In one or more aspects, the sensor interlayer insulating layer 352 can include a thermosetting material or a photocurable material that can be cured by heat or light.

For example, in a process of forming the auxiliary routing lines TLA in the non-display area NDA, a conductive layer can be deposited on the whole sensor buffer layer 351, and a liquid photoresist can be applied on the conductive layer. In this situation, a thickness of the photoresist formed in an area between the dams (DM1 and DM2) can be greater than that of the photoresist formed on the dams (DM1 and DM2). In this situation, when an exposure process is performed based on the thickness of the photoresist formed on the dams (DM1 and DM2), the photoresist with the great thickness in the area between the dams (DM1 and DM2) may not be properly exposed, and thereby, a photoresist residue can remain after a development process. When a conductive layer is patterned in a state where the photoresist residue remains, there can occur a defect where the conductive layer in an area corresponding to the photoresist residue remains and thereby, a short circuit is formed between adjacent auxiliary routing lines TLA. In other words, a bumpy surface created by features like dams can lead to a non-uniform photoresist thickness. This can cause incomplete exposure during photolithography that may leave behind some photoresist residue after development. This residue may then prevent the complete removal of the underlying conductive layer during etching, which can result in unintended conductive material that creates short circuits between adjacent routing lines.

In addition, when the exposure process is performed based on the thickness of the photoresist with the great thickness in the area between the dams (DM1 and DM2), no photoresist residue can occur in the area between the dams (DM1 and DM2), but the exposure amount can increase in other areas, this causing a link portion to be lost. In other words, simply increasing the exposure dose to eliminate unwanted residue between dams can create a new problem. This approach can overexpose thinner photoresist regions, which can destroy fine pattern features and result in open circuits, thus trading one type of failure mode for another.

Taking account of these issues, in one or more aspects, the display device 100 can include a structure where the moisture preventing layer MPL is disposed in an area where a sharp step and a curve are formed located in the non-display area NDA, and the sensor interlayer insulating layer 352 has a sufficient thickness. Thereby, the display device can provide advantages of compensating for a step difference between upper and lower surfaces (or edges) of the at least one dam structure DM and eliminating or reducing short circuiting and/or disconnection of the auxiliary routing lines TLA and the touch routing lines TL. In other words, to address the issues mentioned above, a display device with an improved structure for enhanced reliability is provided, according to an embodiment. For example, a moisture preventing layer MPL can be specifically disposed over areas with sharp topographical variations, such as dam structures and valleys, and is combined with a sensor interlayer insulating layer 352 having sufficient thickness for smoothing out these bumps and valleys. In this way, the configuration can effectively compensate for the step differences caused by the underlying components to create a more planar surface or smoother transitions. For example, this structure can allow for the uniform formation of subsequent conductive layers, which can eliminate or significantly reduce potential defects such as short circuits and disconnections in the device's routing lines, particularly in a bending area of the non-display area NDA.

Referring to FIGS. 5 and 6, the moisture preventing layer MPL can be disposed on the sensor buffer layer 351. The moisture preventing layer MPL can be formed by using a bridge metal BRG. The moisture preventing layer MPL can include the same material as the auxiliary routing lines TLA, but can be disposed in an area where the auxiliary routing lines TLA are disconnected (e.g., the auxiliary routing lines TLA are not disposed). The moisture preventing layer MPL and the auxiliary routing lines TLA can be disconnected (or separated) from each other by disconnection (or separation) areas DCA (e.g., this can help facilitate bending and reducing cracking). The sensor buffer layer 351 and the sensor interlayer insulating layer 352 can contact each other in the disconnection (or separation) areas DCA. In one or more aspects, when the sensor buffer layer 351 is not disposed, a third encapsulation layer 343 and the sensor interlayer insulating layer 352 can be bonded in the disconnection (or separation) areas DCA. According to an embodiment, the encapsulation layer 200 can be disposed between the moisture preventing layer MPL and the at least one dam structure DM. According to an embodiment, the sensor interlayer insulating layer 352 can have a convex upper surface configured to reduce a step difference due to an inclined portion of the moisture preventing layer. The inclined portion of the moisture preventing layer MPL can correspond to an inclined portion of the dam DM.

The moisture preventing layer MPL can be in an electrical floating state. For example, the moisture preventing layer MPL can be in the floating state in which it is not electrically connected to the touch routing lines TL and the auxiliary routing lines TLA. According to an embodiment, the moisture preventing layer MPL can be sealed between the sensor buffer layer 351 and the sensor interlayer insulating layer 352. In addition, the moisture preventing layer MPL can be in the floating state in which it is not connected to other signal lines or voltage lines for driving subpixels SP. As the moisture preventing layer MPL, which is in the electrical floating state, is disposed in an area where a sharp step occurs (e.g., bumps and valleys, etc.), short circuiting or disconnection (or separation) of the auxiliary routing lines TLA can be eliminated or reduced.

The moisture preventing layer MPL can be disposed to overlap with at least a portion of the at least one dam structure DM. The moisture preventing layer MPL can be disposed to overlap with an upper surface and at least one side surface of the at least one dam structure DM. For example, the moisture preventing layer MPL can be disposed such that it extends to an upper surface and an outer side surface of the first dam DM1, an area between the first dam DM1 and the second dam DM2, and an inner side surface, an upper surface, and an outer side surface of the second dam DM2. As the moisture preventing layer MPL is disposed to overlap with at least respective portions of the upper surface and the at least one side surface of the at least one dam structure DM, the penetration of moisture to the inside of the display panel 110 from an area outside of the display panel 110 can be prevented or reduced. According to an embodiment, the moisture preventing layer MPL can provide dual functions of improving uniform bending and blocking moisture penetration.

Further, as the sensor interlayer insulating layer 352 is formed with the sufficient thickness, a step between respective upper areas (or upper surfaces) of the dams (DM1 and DM2) and the area between the dams (DM1 and DM2) can be eliminated or reduced. Thereby, exposure and development can be maintained at a constant level when forming the touch routing lines TL, and short circuiting or disconnection (or separation) of the touch routing lines TL can be prevented or reduced.

The touch routing lines TL can be disposed on the sensor interlayer insulating layer 352. The touch routing lines TL can be formed by using sensor metals TSM. The touch routing lines TL can be disposed to extend from the display area DA to the non-display area NDA. The touch routing lines TL can be disposed to extend to the non-display area NDA and be electrically connected to touch pads TP disposed in an area outward from the at least one dam structure DM. The touch routing lines TL can be electrically connected to the auxiliary routing lines TLA through contact holes formed in the sensor interlayer insulating layer 352. The touch routing lines TL may not be electrically connected to the moisture preventing layer MPL.

The sensor protection layer 353 can be disposed on the touch routing lines TL. The sensor protection layer 353 can include an organic insulating material.

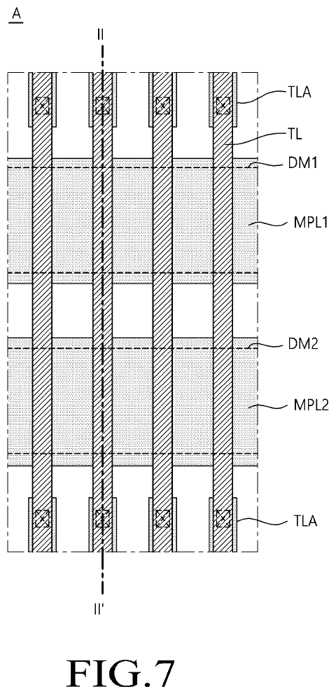

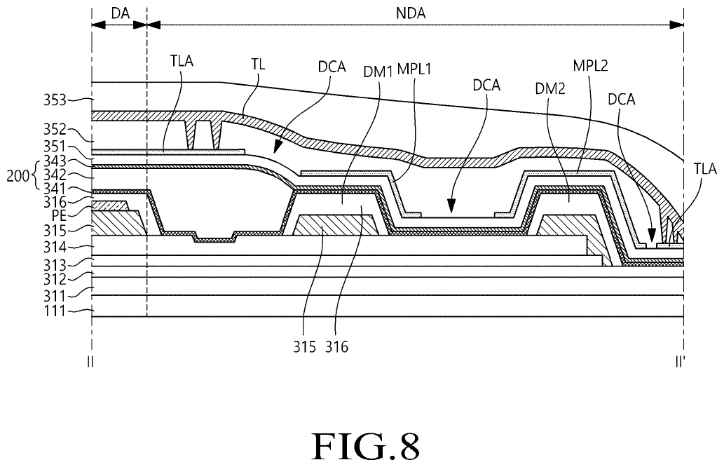

FIG. 7 is another example enlarged view of area A of FIG. 4. FIG. 8 is an example cross-sectional view taken along line II-II′ in FIG. 7. In discussions that follow for the configurations of FIGS. 7 and 8, discussions for features and configurations equal, substantially equal, or similar to the features and configurations described with reference to FIGS. 1 to 6 are omitted or briefly described for convenience of description.

Referring to FIGS. 3, 7 and 8, in one or more example embodiments, the display panel 110 can include the substrate 111, the insulating layers (311, 312, 313, and 314) on the substrate 111, the planarization layer 315, the pixel electrode PE, the bank 316, the encapsulation layer 200, the sensor buffer layer 351, the sensor interlayer insulating layer 352, the sensor protection layer 353, at least one touch routing line TL, at least one auxiliary routing line TLA, at least one moisture preventing layer MPL, and at least one dam structure DM. In discussing configurations of FIGS. 7 and 8, since the configurations already described with reference to FIGS. 5 and 6 except that the at least one auxiliary routing line TLA includes a first moisture preventing layer MPL and a second moisture preventing layer MPL are equally applied to the configurations of FIGS. 7 and 8, therefore, repeated discussions for theses configurations are omitted for conciseness.

Referring to FIGS. 7 and 8, the at least one moisture preventing layer MPL can include the first moisture preventing layer MPL1 and the second moisture preventing layer MPL2. The first moisture preventing layer MPL1 and the second moisture preventing layer MPL2 can be disposed on the sensor buffer layer 351. The first moisture preventing layer MPL1 and the second moisture preventing layer MPL2 can be formed by using bridge metals BRG. The first moisture preventing layer MPL1 and the second moisture preventing layer MPL2 can include the same material as auxiliary routing lines TLA, but can be disposed in areas where the auxiliary routing lines TLA are disconnected (e.g., the auxiliary routing lines TLA are not disposed). The first moisture preventing layer MPL1, the second moisture preventing layer MPL2, and the auxiliary routing lines TLA can be disconnected (or separated) from each other by disconnection (or separation) areas DCA. The sensor buffer layer 351 and the sensor interlayer insulating layer 352 can contact each other in the disconnection (or separation) areas DCA. The first moisture preventing layer MPL1 and the second moisture preventing layer MPL2 can be in an electrical floating state. For example, each of the first moisture preventing layer MPL1 and the second moisture preventing layer MPL2 can be in the floating state in which the first moisture preventing layer MPL1 and the second moisture preventing layer MPL2 are not electrically connected to touch routing lines TL and auxiliary routing lines TLA. According to an embodiment, the first moisture preventing layer MPL1 and the second moisture preventing layer MPL2 can be sealed between the sensor buffer layer 351 and the sensor interlayer insulating layer 352. In addition, the first moisture preventing layer MPL1 and the second moisture preventing layer MPL2 can be in the floating state in which the first moisture preventing layer MPL1 and the second moisture preventing layer MPL2 are not connected to other signal lines or voltage lines for driving subpixels SP. As the first moisture preventing layer MPL1 and the second moisture preventing layer MPL2, which are in the electrical floating state, are disposed in an area where a sharp step occurs (e.g., bumps and valleys), short circuiting or disconnection (or separation) of the auxiliary routing lines TLA can be eliminated or reduced.

The first moisture preventing layer MPL1 and the second moisture preventing layer MPL2 can be disposed to overlap with at least a portion of the at least one dam structure DM. The first moisture preventing layer MPL1 and the second moisture preventing layer MPL2 can be disposed to overlap with an upper surface and at least one side surface of the at least one dam structure DM. For example, the first moisture preventing layer MPL1 can be disposed to overlap with an upper surface and an outer side surface of the first dam DM1. The second moisture preventing layer MPL2 can be disposed to overlap with an inner side surface, an upper surface, and an outer side surface of the second dam DM2. The first moisture preventing layer MPL1 and the second moisture preventing layer MPL2 can be disposed to be spaced apart from each other between the first dam DM1 and the second dam DM2. At least one disconnection (or separation) area DCA can be disposed between the first moisture preventing layer MPL1 and the second moisture preventing layer MPL2. The sensor buffer layer 351 and the sensor interlayer insulating layer 352 can contact each other in the disconnection (or separation) area DCA. As the moisture preventing layer MPL including the first moisture preventing layer MPL1 and the second moisture preventing layer MPL2 is disposed to overlap with at least respective portions of the upper surface and the at least one side surface of the at least one dam structure DM, the penetration of moisture to the inside of the display panel 110 from an area outside of the display panel 110 can be prevented or reduced.

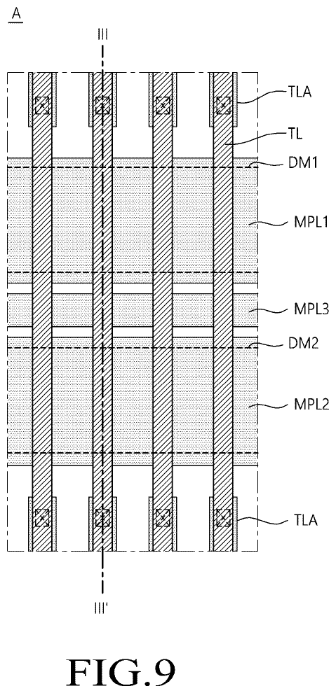

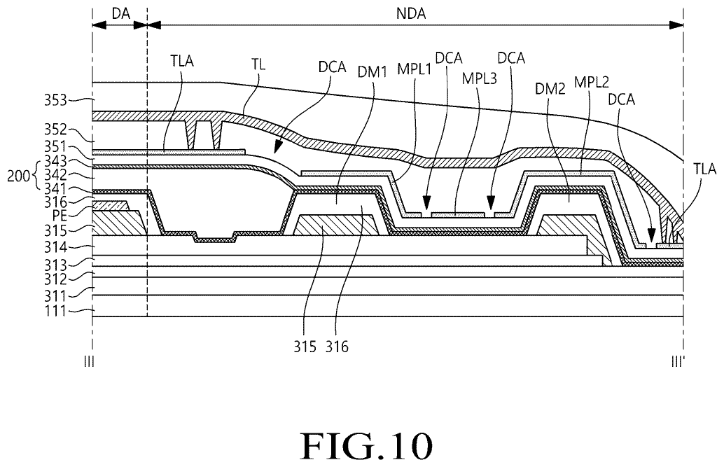

FIG. 9 is another example enlarged view of area A of FIG. 4. FIG. 10 is an example cross-sectional view taken along line III-III′ in FIG. 9. In discussions that follow for the configurations of FIGS. 9 and 10, discussions for features and configurations equal, substantially equal, or similar to the features and configurations described with reference to FIGS. 1 to 8 are omitted or briefly described for convenience of description.

Referring to FIGS. 3, 9 and 10, in one or more example embodiments, the display panel 110 can include the substrate 111, the insulating layers (311, 312, 313, and 314) on the substrate 111, the planarization layer 315, the pixel electrode PE, the bank 316, the encapsulation layer 200, the sensor buffer layer 351, the sensor interlayer insulating layer 352, the sensor protection layer 353, at least one touch routing line TL, at least one auxiliary routing line TLA, at least one moisture preventing layer MPL, and at least one dam structure DM. In discussing configurations of FIGS. 9 and 10, since the configurations already described with reference to FIGS. 5 and 6 except that the at least one auxiliary routing line TLA includes a first moisture preventing layer MPL, a second moisture preventing layer MPL, and a third moisture preventing layer MPL are equally applied to the configurations of FIGS. 9 and 10, therefore, repeated discussions for theses configurations are omitted for conciseness.

Referring to FIGS. 9 and 10, the at least one moisture preventing layer MPL can include the first moisture preventing layer MPL1, the second moisture preventing layer MPL2, and the third moisture preventing layer MPL3. The first moisture preventing layer MPL1, the second moisture preventing layer MPL2, and the third moisture preventing layer MPL3 can be disposed on the sensor buffer layer 351. The first moisture preventing layer MPL1, the second moisture preventing layer MPL2, and the third moisture preventing layer MPL3 can be formed by using bridge metals BRG. The first moisture preventing layer MPL1, the second moisture preventing layer MPL2, and the third moisture preventing layer MPL3 can include the same material as auxiliary routing lines TLA, but can be disposed in areas where the auxiliary routing lines TLA are disconnected (e.g., the auxiliary routing lines TLA are not disposed). The first moisture preventing layer MPL1, the second moisture preventing layer MPL2, the third moisture preventing layer MPL3, and the auxiliary routing lines TLA can be disconnected (or separated) from each other by disconnection (or separation) areas DCA. The sensor buffer layer 351 and the sensor interlayer insulating layer 352 can contact each other in the disconnection (or separation) areas DCA. The first moisture preventing layer MPL1, the second moisture preventing layer MPL2, and the third moisture preventing layer MPL3 can be in an electrical floating state. For example, the first moisture preventing layer MPL1, the second moisture preventing layer MPL2, and the third moisture preventing layer MPL3 can be in the floating state in which the first moisture preventing layer MPL1, the second moisture preventing layer MPL2, and the third moisture preventing layer MPL3 are not electrically connected to touch routing lines TL and auxiliary routing lines TLA. According to an embodiment, the first moisture preventing layer MPL1, the second moisture preventing layer MPL2 and the third moisture preventing layer MPL3 can be sealed between the sensor buffer layer 351 and the sensor interlayer insulating layer 352. In addition, the first moisture preventing layer MPL1, the second moisture preventing layer MPL2, and the third moisture preventing layer MPL3 can be in the floating state in which the first moisture preventing layer MPL1, the second moisture preventing layer MPL2, and the third moisture preventing layer MPL3 are not connected to other signal lines or voltage lines for driving subpixels SP. As the first moisture preventing layer MPL1, the second moisture preventing layer MPL2, and the third moisture preventing layer MPL3, which are in the electrical floating state, are disposed in an area where a sharp step occurs (e.g., ridges and valleys), short circuiting or disconnection (or separation) of the auxiliary routing lines TLA can be eliminated or reduced.

At least one of the first moisture preventing layer MPL1, the second moisture preventing layer MPL2, and the third moisture preventing layer MPL3 can be disposed to overlap with at least a portion of the at least one dam structure DM. The first moisture preventing layer MPL1 and the second moisture preventing layer MPL2 can be disposed to overlap with an upper surface and at least one side surface of the at least one dam structure DM, and the third moisture preventing layer MPL3 can be disposed not to overlap with the at least one dam structure DM. For example, the first moisture preventing layer MPL1 can be disposed to overlap with an upper surface and an outer side surface of the first dam DM1. The second moisture preventing layer MPL2 can be disposed to overlap with an inner side surface, an upper surface, and an outer side surface of the second dam DM2. The third moisture preventing layer MPL3 can be disposed between the first dam DM1 and the second dam DM2, and be spaced apart from the first moisture preventing layer MPL1 and the second moisture preventing layer MPL2. Disconnection (or separation) areas DCA can be disposed between the first moisture preventing layer MPL1, the second moisture preventing layer MPL2, and the third moisture preventing layer MPL3. The sensor buffer layer 351 and the sensor interlayer insulating layer 352 can contact each other in the disconnection (or separation) areas DCA. As the moisture preventing layer MPL including the first moisture preventing layer MPL1, the second moisture preventing layer MPL2, and the third moisture preventing layer MPL3 is disposed to overlap with at least respective portions of the upper surface and the at least one side surface of the at least one dam structure DM, the penetration of moisture to the inside of the display panel 110 from an area outside of the display panel 110 can be prevented or reduced.

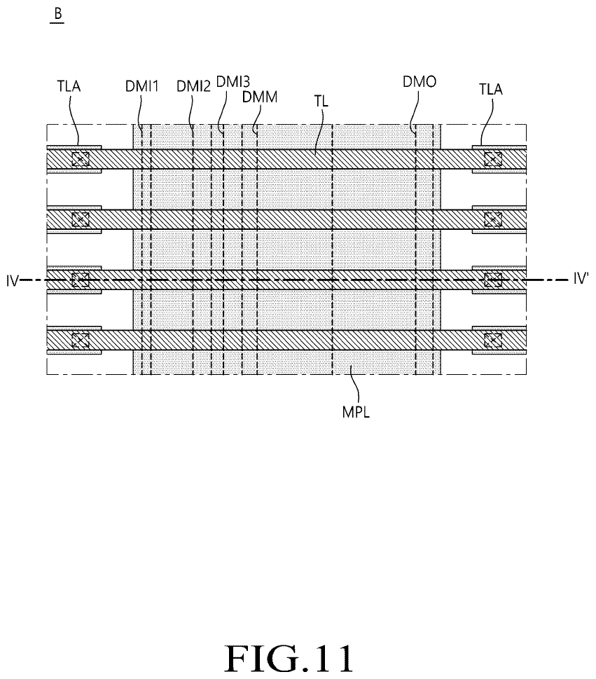

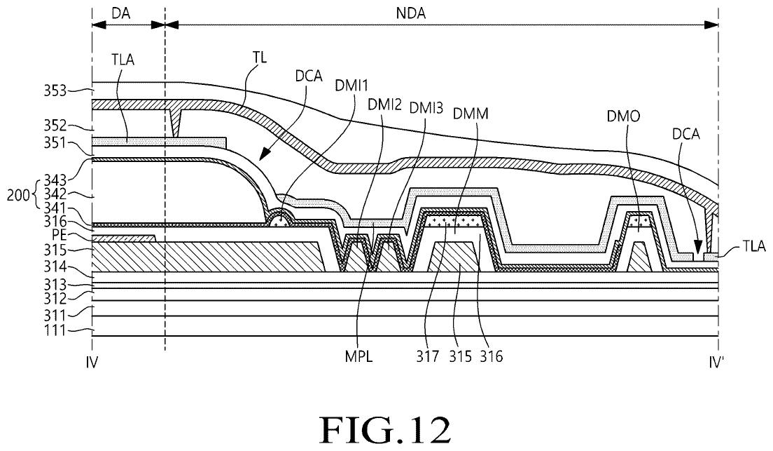

FIG. 11 is an example enlarged view of area B of FIG. 4. FIG. 12 is an example cross-sectional view taken along line IV-IV′ in FIG. 11. In discussions that follow for the configurations of FIGS. 11 and 12, discussions for features and configurations equal, substantially equal, or similar to the features and configurations described with reference to FIGS. 1 to 10 are omitted or briefly described for convenience of description.

Referring to FIGS. 3, 11 and 12, in one or more example embodiments, the display panel 110 can include the substrate 111, the insulating layers (311, 312, 313, and 314) on the substrate 111, the planarization layer 315, the pixel electrode PE, the bank 316, the encapsulation layer 200, the sensor buffer layer 351, the sensor interlayer insulating layer 352, the sensor protection layer 353, at least one touch routing line TL, at least one auxiliary routing line TLA, a moisture preventing layer MPL, and at least one dam structure DM. In discussing configurations of FIGS. 11 and 12, since the configurations already described with reference to FIGS. 5 and 6 except that the at least one dam structure DM includes an inner dam DMI, a main dam DMM, and an outer dam DMO are equally applied to the configurations of FIGS. 11 and 12, therefore, repeated discussions for theses configurations are omitted for conciseness.

Referring to FIGS. 11 and 12, touch routing lines TL can be disposed to extend from the display area DA to the non-display area NDA. Auxiliary routing lines TLA can be disposed to be overlapped with the touch routing lines TL in a plan view. The touch routing lines TL and the auxiliary routing lines TLA can be electrically connected through contact holes.

The at least one dam structure DM can be located in an area outward from the display area DA. For example, the at least one dam structure DM can include the inner dam DMI, the main dam DMM, and the outer dam DMO. The inner dam DMI can include a first inner dam DMI1, a second inner dam DMI2, and a third inner dam DMI3. The inner dam DMI can be located between the display area DA and the main dam DMM. The main dam DMM can be located between the inner dam DMI and the outer dam DMO. The at least one dam structure DM can be formed by using at least respective portions of layers (e.g., the planarization 315, the bank 316, a spacer, and the like) disposed in the display area DA. The at least one dam structure DM can be surrounded by a portion of the encapsulation layer 200. A pad area PA can be located in an area outward from the at least one dam structure DM.

Referring to FIGS. 11 and 12, the moisture preventing layer MPL can be disposed on the sensor buffer layer 351. For example, the moisture preventing layer MPL can be configuration as a large, uniform sheet or rectangle in a plan view, but embodiments are not limited thereto. The moisture preventing layer MPL can be formed by using a bridge metal BRG. The moisture preventing layer MPL can include the same material as the auxiliary routing lines TLA, but can be disposed in an area where the auxiliary routing lines TLA are disconnected (e.g., the auxiliary routing lines TLA are not disposed). The moisture preventing layer MPL and the auxiliary routing lines TLA can be disconnected (or separated) from each other by disconnection (or separation) areas DCA. The sensor buffer layer 351 and the sensor interlayer insulating layer 352 can contact each other in the disconnection (or separation) areas DCA. The moisture preventing layer MPL can be in an electrical floating state. For example, the moisture preventing layer MPL can be in the floating state in which it is not electrically connected to the touch routing lines TL and the auxiliary routing lines TLA. According to an embodiment, the moisture preventing layer MPL can be sealed between the sensor buffer layer 351 and the sensor interlayer insulating layer 352. In addition, the moisture preventing layer MPL can be in the floating state in which it is not connected to other signal lines or voltage lines for driving subpixels SP. As the moisture preventing layer MPL, which is in the electrical floating state, is disposed in an area where a sharp step occurs, short circuiting or disconnection (or separation) of the auxiliary routing lines TLA can be eliminated or reduced.

The moisture preventing layer MPL can be disposed to overlap with at least a portion of the at least one dam structure DM. The moisture preventing layer MPL can be disposed to overlap with an upper surface and at least one side surface of the at least one dam structure DM. For example, the moisture preventing layer MPL can be disposed to overlap with an upper surface and an outer side surface of the first inner dam DMI1. The moisture preventing layer MPL can be disposed to overlap with the upper surface and the outer side surface of the first inner dam DMI1. The moisture preventing layer MPL can be disposed to overlap with an upper surface and at least one side surface of the second inner dam DMI2. The moisture preventing layer MPL can be disposed to overlap with an upper surface and at least one side surface of the third inner dam DMI3. The moisture preventing layer MPL can be disposed to overlap with an upper surface and at least one side surface of the main dam DMM. The moisture preventing layer MPL can be disposed to overlap with an upper surface and at least one side surface of the outer dam DMO. The moisture preventing layer MPL can be integrally disposed from the first inner dam DMI1 to the outer dam DMO. As the moisture preventing layer MPL is disposed to overlap with at least a portion of the upper surface and the at least one side surface of the at least one dam structure DM, the penetration of moisture to the inside of the display panel 110 from an area outside of the display panel 110 can be prevented or reduced. For example, according to an embodiment, the moisture preventing layer MPL can be configured as a uniform sheet structure that continuously extends across multiples dams and valleys.

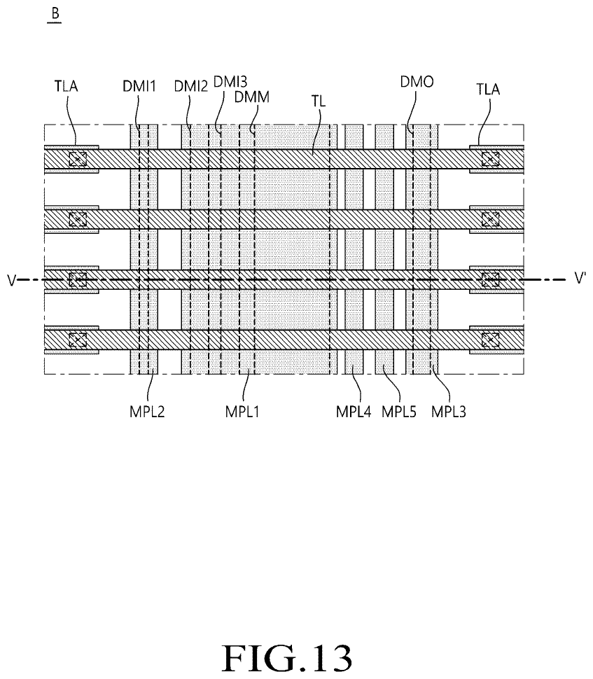

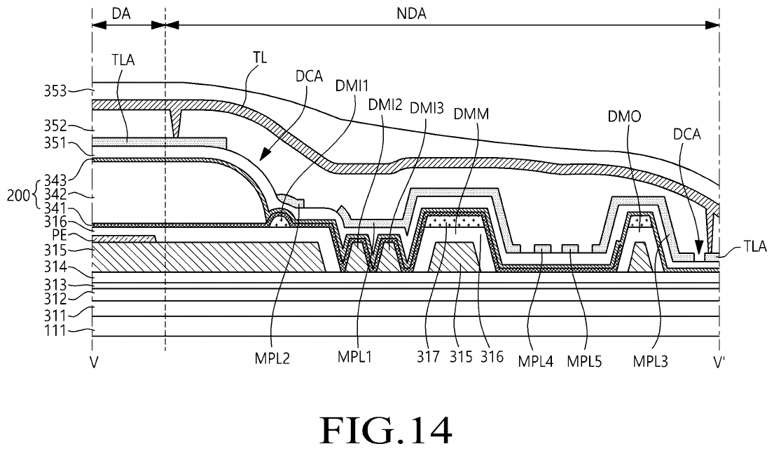

FIG. 13 is another example enlarged view of area B of FIG. 4. FIG. 14 is an example cross-sectional view taken along line V-V′ in FIG. 13. In discussions that follow for configurations of FIGS. 13 and 14, discussions for features and configurations equal, substantially equal, or similar to the features and configurations described with reference to FIGS. 1 to 12 are omitted or briefly described for convenience of description.

Referring to FIGS. 3, 13 and 14, in one or more example embodiments, the display panel 110 can include the substrate 111, the insulating layers (311, 312, 313, and 314) on the substrate 111, the planarization layer 315, the pixel electrode PE, the bank 316, the encapsulation layer 200, the sensor buffer layer 351, the sensor interlayer insulating layer 352, the sensor protection layer 353, at least one touch routing line TL, at least one auxiliary routing line TLA, at least one moisture preventing layer MPL, and at least one dam structure DM. In discussing configurations of FIGS. 13 and 14, since the configurations already described with reference to FIGS. 11 and 12 except that the at least one moisture preventing layer MPL includes a first moisture preventing layer MPL1, a second moisture preventing layer MPL2, a third moisture preventing layer MPL3, a fourth moisture preventing layer MPL4, and a fifth moisture preventing layer MPL5 are equally applied to the configurations of FIGS. 13 and 14, therefore, repeated discussions for theses configurations are omitted for conciseness. For example, according to an embodiment, the moisture preventing layer MPL can be configured as a plurality of strips of various widths that are separated from each other, in which the multiple strips can be perpendicular to the touch routing lines TL. For example, a width of the first moisture preventing layer MPL1 can be greater than the second moisture preventing layer MPL2 and the third moisture preventing layer MPL3, and widths of the second moisture preventing layer MPL2 and the third moisture preventing layer MPL3 can be greater than widths of the fourth moisture preventing layer MPL4 and the fifth moisture preventing layer MPL5.

Referring to FIGS. 13 and 14, the moisture preventing layer MPL can include the first moisture preventing layer MPL1, the second moisture preventing layer MPL2, the third moisture preventing layer MPL3, the fourth moisture preventing layer MPL4, and the fifth moisture preventing layer MPL5. The first moisture preventing layer MPL1, the second moisture preventing layer MPL2, the third moisture preventing layer MPL3, the fourth moisture preventing layer MPL4, and the fifth moisture preventing layer MPL5 can be disposed on the sensor buffer layer 351. The first moisture preventing layer MPL1, the second moisture preventing layer MPL2, the third moisture preventing layer MPL3, the fourth moisture preventing layer MPL4, and the fifth moisture preventing layer MPL5 can be formed by using bridge metals BRG. The first moisture preventing layer MPL1, the second moisture preventing layer MPL2, the third moisture preventing layer MPL3, the fourth moisture preventing layer MPL4, and the fifth moisture preventing layer MPL5 can include the same material as auxiliary routing lines TLA, but can be disposed in areas where the auxiliary routing lines TLA are disconnected (i.e., the auxiliary routing lines TLA are not disposed). The first moisture preventing layer MPL1, the second moisture preventing layer MPL2, the third moisture preventing layer MPL3, the fourth moisture preventing layer MPL4, the fifth moisture preventing layer MPL5, and the auxiliary routing lines TLA can be disconnected (or separated) from each other by disconnection (or separation) areas DCA. The sensor buffer layer 351 and the sensor interlayer insulating layer 352 can contact each other in the disconnection (or separation) areas DCA. The first moisture preventing layer MPL1, the second moisture preventing layer MPL2, the third moisture preventing layer MPL3, the fourth moisture preventing layer MPL4, and the fifth moisture preventing layer MPL5 can be in an electrical floating state. For example, the first moisture preventing layer MPL1, the second moisture preventing layer MPL2, the third moisture preventing layer MPL3, the fourth moisture preventing layer MPL4, and the fifth moisture preventing layer MPL5 can be in the floating state in which the first moisture preventing layer MPL1, the second moisture preventing layer MPL2, the third moisture preventing layer MPL3, the fourth moisture preventing layer MPL4, and the fifth moisture preventing layer MPL5 are not electrically connected to touch routing lines TL and auxiliary routing lines TLA. According to an embodiment, the first moisture preventing layer MPL1, the second moisture preventing layer MPL2, the third moisture preventing layer MPL3, the fourth moisture preventing layer MPL4, and the fifth moisture preventing layer MPL5 can be sealed between the sensor buffer layer 351 and the sensor interlayer insulating layer 352. In addition, the first moisture preventing layer MPL1, the second moisture preventing layer MPL2, the third moisture preventing layer MPL3, the fourth moisture preventing layer MPL4, and the fifth moisture preventing layer MPL5 can be in the floating state in which the first moisture preventing layer MPL1, the second moisture preventing layer MPL2, the third moisture preventing layer MPL3, the fourth moisture preventing layer MPL4, and the fifth moisture preventing layer MPL5 are not connected to other signal lines or voltage lines for driving subpixels SP. As the first moisture preventing layer MPL1, the second moisture preventing layer MPL2, the third moisture preventing layer MPL3, the fourth moisture preventing layer MPL4, and the fifth moisture preventing layer MPL5, which are in the electrical floating state, are disposed in an area where a sharp step occurs, short circuiting or disconnection (or separation) of the auxiliary routing lines TLA can be eliminated or reduced.

At least one of the first moisture preventing layer MPL1, the second moisture preventing layer MPL2, the third moisture preventing layer MPL3, the fourth moisture preventing layer MPL4, and the fifth moisture preventing layer MPL5 can be disposed to overlap with at least a portion of the at least one dam structure DM. For example, the first moisture preventing layer MPL1 can be disposed to overlap with an upper surface and at least one side surface of the main dam DMM. The first moisture preventing layer MPL1 can be disposed to overlap with an upper surface and at least one side surface of the second inner dam DMI2. The first moisture preventing layer MPL1 can be disposed to overlap with an upper surface and at least one side surface of the third inner dam DMI3. The first moisture preventing layer MPL1 can be disposed integrally from the second inner dam DMI2 to the main dam DMM. The second moisture preventing layer MPL2 can be disposed to overlap with an upper surface and an outer side surface of the first inner dam DMI. The third moisture preventing layer MPL3 can be disposed to overlap with an upper surface and at least one side surface of the outer dam DMO. The fourth moisture preventing layer MPL4 and the fifth moisture preventing layer MPL5 can be disposed not to overlap with the at least one dam structure DM. For example, the first moisture preventing layer MPL1 can be disposed to overlap with the upper surface, inner side surface, and outer side surface of the main dam DMM. The first moisture preventing layer MPL1 can be disposed to overlap the upper surface, inner side surface, and outer side surface of the second inner dam DMI2. The first moisture preventing layer MPL1 can be disposed to overlap with the upper surface, inner side surface, and outer side surface of the third inner dam DMI3. The first moisture preventing layer MPL1 can be disposed integrally from the second inner dam DMI2 to the main dam DMM. The second moisture preventing layer MPL2 can be disposed to overlap with the upper surface and an outer side surface of the first inner dam DMI. The third moisture preventing layer MPL3 can be disposed to overlap with the upper surface, inner side surface, and outer side surface of the third inner dam DMI3. of the outer dam DMO. The fourth moisture preventing layer MPL4 and the fifth moisture preventing layer MPL5 can be disposed between the main dam DMM and the outer dam DMO, and spaced apart from the first moisture preventing layer MPL1 and the third moisture preventing layer MPL3. Disconnection (or separation) areas DCA can be disposed between the first moisture preventing layer MPL1, the second moisture preventing layer MPL2, the third moisture preventing layer MPL3, the fourth moisture preventing layer MPL4, and the fifth moisture preventing layer MPL5. The sensor buffer layer 351 and the sensor interlayer insulating layer 352 can contact each other in the disconnection (or separation) areas DCA. As the moisture preventing layer MPL including the first moisture preventing layer MPL1, the second moisture preventing layer MPL2, the third moisture preventing layer MPL3, the fourth moisture preventing layer MPL4, and the fifth moisture preventing layer MPL5 is disposed to overlap with at least respective portions of the upper surface and the at least one side surface of the at least one dam structure DM, the penetration of moisture to the inside of the display panel 110 from an area outside of the display panel 110 can be prevented or reduced.

According to an embodiment, a display device can be provided which has a configuration that significantly improves device reliability by employing a multi-layer, protective structure. For example, this configuration can include, inter alia, a moisture barrier, a buffer and a thick insulating layer that can planarize the display device's internal topography, particularly in a routing line area that corresponding to a bending area, which can be sensitive to various issues (e.g., cracking, peeling, moisture penetration, etc.). By creating a smooth, uniform foundation over underlying structural irregularities, the configuration can help ensure precise and reliable formation of conductive patterns, which can reduce or prevent common manufacturing defects.

The examples, aspects, and embodiments for the display device 100 and the display panel 110 described herein can be described as follows.

According to the one or more example embodiments described herein, a display device can include a substrate including a display area and a non-display area outside of the display area, display area including subpixels, a dam disposed in the non-display area, an encapsulation layer disposed on the subpixels and the dam, at least one auxiliary routing line disposed on a portion of the encapsulation layer, the at least one auxiliary routing line can not overlap with the dam, a moisture preventing layer disposed on the encapsulation layer and overlapping with the dam, a sensor interlayer insulating layer disposed on the at least one auxiliary routing line and the moisture preventing layer, and at least one touch routing line disposed on the sensor interlayer insulating layer and electrically connected to the auxiliary routing line.

In one or more aspects, in the display device, the moisture preventing layer can be disposed on a same layer as the auxiliary routing line. In one or more aspects, the moisture preventing layer can be spaced apart from the auxiliary routing line.

In one or more aspects, the display device can include a disconnection area disposed between the moisture preventing layer and the auxiliary routing line. In one or more aspects, the sensor interlayer insulating layer can contact a layer disposed under the moisture preventing layer and the auxiliary routing line in the disconnection area.

In one or more aspects, in the display device, the auxiliary routing line and the moisture preventing layer can include a same material.

In one or more aspects, in the display device, the moisture preventing layer can be in an electrical floating state.

In one or more aspects, in the display device, the moisture preventing layer can overlap with an upper surface of the dam and at least one side surface of the dam.

In one or more aspects, in the display device, the dam can include a first dam and a second dam disposed spaced apart from the first dam. In one or more aspects, the moisture preventing layer can overlap with at least a portion of the first dam and at least a portion of the second dam.

In one or more aspects, in the display device, the moisture preventing layer can extend across first dam and the second dam.

In one or more aspects, in the display device, the moisture preventing layer can include a first moisture preventing layer overlapping with at least a portion of the first dam, and a second moisture preventing layer overlapping with at least a portion of the second dam.

In one or more aspects, in the display device, the moisture preventing layer can include a third moisture preventing layer located between the first dam and the second dam. In one or more aspects, the third moisture preventing layer can not overlap with the first dam and the second dam.

In one or more aspects, in the display device, the dam can include an inner dam, a main dam, and an outer dam. In one or more aspects, the moisture preventing layer can overlap with portions of the inner dam, the main dam, and the outer dam.

In one or more aspects, in the display device, the moisture preventing layer can extend across the inner dam, the main dam, and the outer dam.

In one or more aspects, in the display device, the moisture preventing layer can include a first moisture preventing layer overlapping with the inner dam and the main dam, a second moisture preventing layer overlapping with at least a portion of the inner dam, and a third moisture preventing layer overlapping with at least a portion of the outer dam.

In one or more aspects, in the display device, the inner dam can include a first inner dam, a second inner dam, and a third inner dam. In one or more aspects, the first moisture preventing layer can overlap with the second inner dam, the third inner dam, and the main dam. In one or more aspects, the second moisture preventing layer can overlap with the first inner dam.

In one or more aspects, in the display device, the moisture preventing layer can further include a fourth moisture preventing layer and a fifth moisture preventing layer located between the main dam and the outer dam. In one or more aspects, the fourth moisture preventing layer and the fifth moisture preventing layer can not overlap with the main dam and the outer dam.

In one or more aspects, in the display device, the sensor interlayer insulating layer can include an inorganic insulating material or an organic insulating material.

In one or more aspects, the display device can further include a sensor protection layer disposed on the touch routing line. In one or more aspects, the sensor protection layer can include an organic insulating material.

In one or more aspects, the display device can further include a touch pad located in the non-display area. In one or more aspects, the touch pad can be disposed in an area outside of the dam. In one or more aspects, the touch pad can be electrically connected to the touch routing line.

According to the one or more example embodiments described herein, a display device can include a plurality of subpixels disposed in a display area of a substrate, a dam disposed in a non-display area of the substrate located outside of the display area, adjacent auxiliary routing lines disposed on opposite sides of the dam, the adjacent auxiliary routing lines being separated from each other, a moisture preventing layer disposed between the adjacent auxiliary routing lines and overlapping with the dam, a sensor interlayer insulating layer extending across the adjacent auxiliary routing lines and the moisture preventing layer, and a touch routing line disposed on the sensor interlayer insulating layer and electrically connected between the adjacent auxiliary routing lines.

In one or more aspects, the display device, the sensor interlayer insulating layer can have a thickness sufficient to substantially planarize a step height associated with the dam.

According to the one or more aspects described herein, a display device can be provided that is capable of reducing or preventing moisture from entering the inside of a display panel from an area outside of the display panel by including a moisture preventing layer.

According to the one or more aspects described herein, a display device can be provided that is capable of compensating for a step difference between upper and lower surfaces (or edges) of a dam structure by including a sensor interlayer insulating layer including an organic material.

According to the one or more aspects described herein, a display device can be provided that is capable of eliminating or reducing the occurrence of short circuiting or disconnection (or separation) of touch lines by compensating for a step difference between upper and lower surfaces (or edges) of a dam structure.

According to the one or more aspects described herein, a display device can be provided that is capable of enabling process optimization by maintaining an appropriate exposure process.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein can be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical features of the present disclosure.

What is claimed is:

1. A display device comprising:
a substrate including a display area and a non-display area outside of the display area, the display area including subpixels;
a dam disposed in the non-display area;
an encapsulation layer disposed on the subpixels and the dam;
at least one auxiliary routing line disposed on a portion of the encapsulation layer, wherein the at least one auxiliary routing line does not overlap with the dam;
a moisture preventing layer disposed on the encapsulation layer and overlapping with the dam;
a sensor interlayer insulating layer disposed on the at least one auxiliary routing line and the moisture preventing layer; and
at least one touch routing line disposed on the sensor interlayer insulating layer and electrically connected to the auxiliary routing line.

2. The display device of claim 1, wherein the moisture preventing layer is disposed on a same layer as the auxiliary routing line, and
wherein the moisture preventing layer is spaced apart from the auxiliary routing line.

3. The display device of claim 2, further comprising a disconnection area disposed between the moisture preventing layer and the auxiliary routing line,
wherein in the disconnection area, the sensor interlayer insulating layer contacts a layer disposed under the moisture preventing layer and the auxiliary routing line.

4. The display device of claim 1, wherein the auxiliary routing line and the moisture preventing layer include a same material.

5. The display device of claim 1, wherein the moisture preventing layer is in an electrical floating state.

6. The display device of claim 1, wherein the moisture preventing layer overlaps with an upper surface of the dam and at least one side surface of the dam.

7. The display device of claim 6, wherein the dam includes a first dam and a second dam disposed spaced apart from the first dam, and
wherein the moisture preventing layer overlaps with at least a portion of the first dam and at least a portion of the second dam.

8. The display device of claim 7, wherein the moisture preventing layer extends across the first dam and the second dam.

9. The display device of claim 7, wherein the moisture preventing layer includes:
a first moisture preventing layer overlapping with at least a portion of the first dam; and
a second moisture preventing layer overlapping with at least a portion of the second dam.

10. The display device of claim 9, wherein the moisture preventing layer includes a third moisture preventing layer located between the first dam and the second dam, and wherein third moisture preventing layer does not overlap with the first dam and the second dam.

11. The display device of claim 6, wherein the dam includes an inner dam, a main dam, and an outer dam, and
wherein the moisture preventing layer overlaps with portions of the inner dam, the main dam, and the outer dam.

12. The display device of claim 11, wherein the moisture preventing layer extends across the inner dam, the main dam, and the outer dam.

13. The display device of claim 11, wherein the moisture preventing layer includes:
a first moisture preventing layer overlapping with the inner dam and the main dam;
a second moisture preventing layer overlapping with at least a portion of the inner dam; and
a third moisture preventing layer overlapping with at least a portion of the outer dam.

14. The display device of claim 13, wherein the inner dam includes a first inner dam, a second inner dam, and a third inner dam,
wherein the first moisture preventing layer overlaps with the second inner dam, the third inner dam, and the main dam, and
wherein the second moisture preventing layer overlaps with the first inner dam.

15. The display device of claim 14, wherein the moisture preventing layer further includes a fourth moisture preventing layer and a fifth moisture preventing layer located between the main dam and the outer dam, and
wherein the fourth moisture preventing layer and the fifth moisture preventing layer does not overlap with the main dam and the outer dam.

16. The display device of claim 1, wherein the sensor interlayer insulating layer includes an inorganic insulating material or an organic insulating material.

17. The display device of claim 16, further comprising a sensor protection layer disposed on the touch routing line,
wherein the sensor protection layer includes an organic insulating material.

18. The display device of claim 1, further comprising a touch pad located in the non-display area,
wherein the touch pad is disposed in an area outside of the dam and the touch pad is electrically connected to the touch routing line.

19. A display device comprising:
a plurality of subpixels disposed in a display area of a substrate;
a dam disposed in a non-display area of the substrate located outside of the display area;
adjacent auxiliary routing lines disposed on opposite sides of the dam, the adjacent auxiliary routing lines being separated from each other;
a moisture preventing layer disposed between the adjacent auxiliary routing lines and overlapping with the dam;
a sensor interlayer insulating layer extending across the adjacent auxiliary routing lines and the moisture preventing layer; and
a touch routing line disposed on the sensor interlayer insulating layer and electrically connected between the adjacent auxiliary routing lines.

20. The display device of claim 19, wherein the sensor interlayer insulating layer has a thickness sufficient to substantially planarize a step height associated with the dam.
